(19) United States
(12) Patent Application Publication
(10) Pub. No.: US 2025/0254903 A1
(43) Pub. Date: Aug. 7, 2025

(54) SEMICONDUCTOR DEVICE

(71) Applicant: SAMSUNG ELECTRONICS CO., LTD., Suwon-si (KR)

(72) Inventors: Joonyong Kim, Suwon-si (KR); In Jun Hwang, Suwon-si (KR)

(21) Appl. No.: 18/818,326

(22) Filed: Aug. 28, 2024

(30) Foreign Application Priority Data
Feb. 6, 2024 (KR) 10-2024-0018370

(51) Int. Cl. H01L 29/778; H01L 23/64; H01L 29/66

(52) U.S. Cl. CPC H10D 30/475; H01L 23/647; H10D 30/015

(57) ABSTRACT

A semiconductor device includes a substrate, a channel pattern, and a first contact electrode and a second contact electrode that are in contact with the side of the drift area and positioned spaced apart from each other in one direction. The channel pattern extends in one direction over the substrate, includes a drift area with a 2-dimensional electron gas, and includes GaN. The resistance of the drift area has a positive temperature coefficient of resistance, a first contact resistance between the first contact electrode and the channel pattern and a second contact resistance between the second contact electrode and the channel pattern have a negative temperature coefficient of resistance, and the sum of the resistance of the drift area of the channel pattern positioned between the first contact electrode and the second contact electrode, the first contact resistance, and the second contact resistance is constant regardless of a temperature.

### CROSS-REFERENCE TO RELATED APPLICATION

This application claims priority to and the benefit of Korean Patent Application No. 10-2024-0018370 filed in the Korean Intellectual Property Office on Feb. 6, 2024, the entire contents of which are incorporated herein by reference.

### BACKGROUND

In modern society, semiconductor devices are closely related to a daily life. In particular, an importance of electric power semiconductor devices used in various fields such as transportation fields such as electric vehicles, railways, and electric trams, renewable energy systems such as solar power generation and wind power generation, and mobile devices is gradually increasing. The electric power semiconductor device is a semiconductor device used to handle high voltage or high current, and performs functions such as an electric power conversion and a control in large-sized electric power systems or high power electronic devices. The electric power semiconductor devices have an ability and durability to handle high electric power, thereby handling large amounts of currents, and withstanding high voltages. For example, the electric power semiconductor device can handle voltages of hundreds to thousands of bolts and currents of tens of amperes to thousands of amperes. The electric power semiconductor devices may improve an efficiency of an electrical energy by minimizing a power loss. Additionally, the electric power semiconductor devices may be operated stably even in environments such as high temperature.

These electric power semiconductor devices may be classified depending on a material, and examples may include a SiC electric power semiconductor device and a GaN electric power semiconductor device. By manufacturing the electric power semiconductor devices by using SiC or GaN instead of conventional silicon wafers (Si wafers), drawbacks of silicon, which has unstable characteristics at high temperatures, may be compensated. The SiC electric power semiconductor device may be resistant to high temperatures and have low power loss, and may be suitable for electric vehicles, renewable energy systems, etc. The GaN electric power semiconductor device requires high costs, but may be efficient in terms of a speed and may be suitable for high-speed charging of mobile devices.

### SUMMARY

This disclosure provides a semiconductor device with stable electric characteristics and improved reliability.

A semiconductor device according to some implementations includes a substrate, a channel pattern that extends in one direction over the substrate, includes a drift area with a 2-dimensional electron gas, and including GaN, and a first contact electrode and a second contact electrode that are in contact with the side of the drift area and positioned spaced apart from each other in one direction, wherein the resistance of the drift area has a positive temperature coefficient of resistance, a first contact resistance between the first contact electrode and the channel pattern and a second contact resistance between the second contact electrode and the channel pattern have a negative temperature coefficient of resistance, and the sum of the resistance of the drift area of the channel pattern positioned between the first contact electrode and the second contact electrode, the first contact resistance, and the second contact resistance is constant regardless of a temperature.

A semiconductor device according to some implementations is a semiconductor device including a main element area and a peripheral circuit area positioned on at least one side of the main element area, wherein the main element area includes a main channel layer, a barrier layer positioned above the main channel layer and including a material having a different energy band gap from the main channel layer, a gate electrode positioned above the barrier layer, a gate semiconductor layer positioned between the barrier layer and the gate electrode, a source electrode and a drain electrode positioned on both sides of the gate electrode and connected to the main channel layer, and a protective layer covering the barrier layer and the gate electrode, the peripheral circuit area includes a channel pattern including a drift area with a 2-dimensional electron gas and including the same material as the main channel layer, and a resistance unit positioned on the channel pattern, including the same material as the source electrode, and having a first contact electrode and a second contact electrode positioned spaced apart from each other in one direction, and the length of the channel pattern between the first contact electrode and the second contact electrode along one direction is 1 μm to 10 μm.

A semiconductor device according to some implementations is a semiconductor device including a main element area and a peripheral circuit area positioned on one side of the main element area and including a plurality of resistance units, wherein the main element area includes a main channel layer including GaN, a barrier layer positioned on the main channel layer and including AlGaN, a gate electrode positioned on the barrier layer, a gate semiconductor layer positioned between the barrier layer and the gate electrode and including GaN doped with a P-type impurity, a source electrode and a drain electrode positioned on both sides of the gate electrode and connected to the main channel layer, and a protective layer covering the barrier layer and the gate electrode, each of the plurality of resistance units includes a channel pattern extending in one direction and integrated with the main channel layer, and a first contact electrode and a second contact electrode positioned on the channel pattern, including the same material as the source electrode, and spaced apart from each other in one direction, and the length of the channel pattern along one direction between the first contact electrode and the second contact electrode of each of the plurality of resistance units is the same.

According to some implementations, the electric characteristics and the reliability of the semiconductor device may be improved.

### BRIEF DESCRIPTION OF THE DRAWINGS

FIG. 1 is a top plan view showing a semiconductor device according to some implementations.

FIG. 2 and FIG. 3 are cross-sectional views cut along a line A-A′ in FIG. 1.

FIG. 4 is a top plan view showing a resistance unit of a semiconductor device according to some implementations.

FIG. 5 is a cross-sectional view cut along a line B-B′ in FIG. 4.

FIG. 6 is a cross-sectional view showing a semiconductor device according to some implementations and corresponding to a line B-B′ of FIG. 4.

FIG. 7 is a circuit diagram showing a resistance unit of a semiconductor device according to some implementations.

FIG. 8 is a graph showing a resistance according to temperature change of a resistance unit of a semiconductor device according to some implementations.

FIG. 9 is a top plan view showing a resistance unit of a semiconductor device according to some implementations.

FIG. 10 is a circuit diagram showing a resistance unit of a semiconductor device in FIG. 9.

FIG. 11 is a top plan view showing a resistance unit of a semiconductor device according to some implementations.

FIG. 12 is a cross-sectional view cut along a line C-C′ in FIG. 11. FIG. 13 is a circuit diagram showing a resistance unit of a semiconductor device of FIG. 11. FIG. 14 is a top plan view showing a resistance unit of a semiconductor device according to some implementations.

FIG. 15 is a cross-sectional view cut along a line D-D′ of FIG. 14.

FIG. 16 to FIG. 18 are top plan views showing a resistance unit of a semiconductor device according to some implementations. FIG. 19 is a cross-sectional view cut along a line E-E′ of FIG. 18.

FIG. 20 is a circuit diagram showing a resistance unit of a semiconductor device of FIG. 18.

FIG. 21 is a top plan view showing a resistance unit of a semiconductor device according to some implementations.

FIG. 22 is a circuit diagram showing a resistance unit of a semiconductor device of FIG. 21.

FIG. 23 is a top plan view showing a semiconductor device according to some implementations.

FIG. 24 to FIG. 30 are process cross-sectional views showing a method of manufacturing a semiconductor device in process order according to some implementations.

### DETAILED DESCRIPTION

The disclosure will be described more fully hereinafter with reference to the accompanying drawings, in which implementations of the invention are shown. As those skilled in the art would realize, the described embodiments may be modified in various different ways, all without departing from the spirit or scope of the disclosure.

Parts unrelated to the description of the implementations are not shown to make the description clear, and like reference numerals designate like element throughout the specification.

The size and thickness of the configurations are shown in the drawings for convenience of description, and the disclosure is not limited to the drawings. In the drawings, the thickness of layers, films, panels, areas, etc., are exaggerated for clarity. In the drawings, for understanding and ease of description, the thickness of some layers and areas is exaggerated.

It will be understood that when an element such as a layer, film, area, or substrate is referred to as being “on” another element, it can be directly on the other element or intervening elements may also be present. In contrast, when an element is referred to as being “directly on” another element, there are no intervening elements present. Further, in the specification, the word “on” or “above” means positioning on or above an object portion, but does not essentially mean positioning on the upper side of the object portion along a gravity direction.

In addition, unless explicitly described to the contrary, the word “comprise”, and variations such as “comprises” or “comprising”, will be understood to imply the inclusion of stated elements but not the exclusion of any other elements.

Further, throughout the specification, the word “on a plane” means viewing a target portion from the top, and the word “on a cross section” means viewing a cross section formed by vertically cutting a target portion from the side.

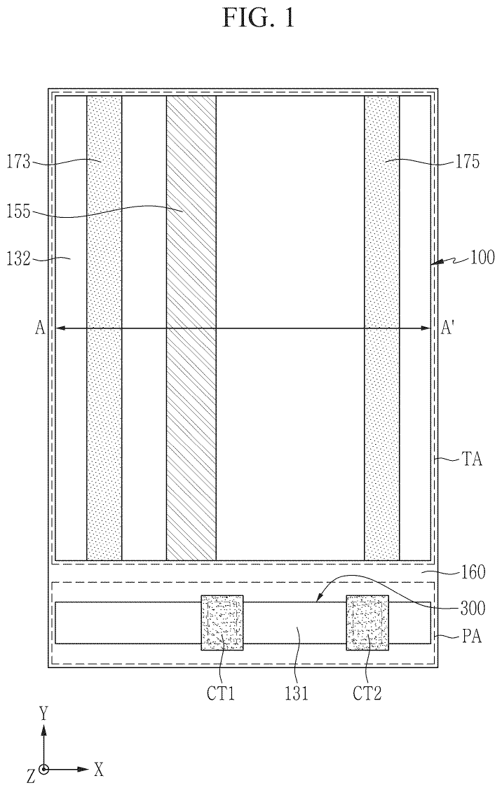

Hereinafter, a semiconductor device according to some implementations is described with reference to FIG. 1 to FIG. 3.

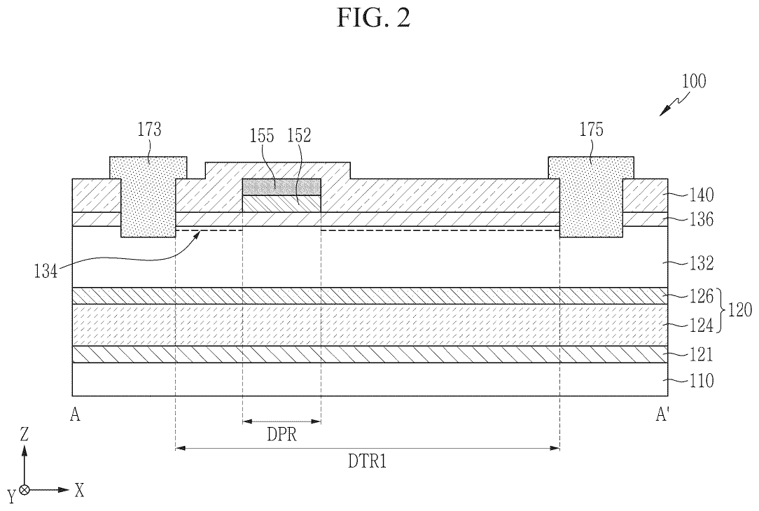

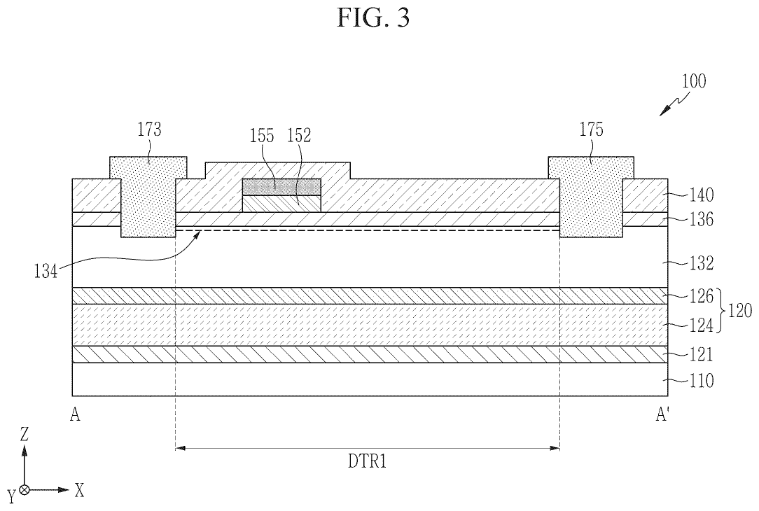

FIG. 1 is a top plan view showing a semiconductor device according to some implementations. FIG. 2 and FIG. 3 are cross-sectional views cut along a line A-A′ in FIG. 1

FIG. 2 represents a case where the semiconductor device according to some implementations is in an off state. FIG. 3 represents a case where the semiconductor device according to some implementations is in an on state.

First, as shown in FIG. 1, a semiconductor device according to some implementations includes a main element area TA and a peripheral circuit area PA.

A semiconductor unit 100 may be placed in the main element area TA. For example, the semiconductor unit 100 of the semiconductor device according to some implementations may be a normally off high electron mobility transistor (HEMT). However, it is not limited thereto, the semiconductor unit 100 of the semiconductor device according to some implementations may be a normally on high electron mobility transistor. That is, in some implementations, the main element area TA may mean an area where the semiconductor unit 100 is placed.

Additionally, the peripheral circuit area PA may include elements that are electrically connected to the semiconductor unit 100. For example, a resistance unit 300 electrically connected to the semiconductor unit 100 may be positioned within the peripheral circuit area PA of the semiconductor device according to some implementations. In some implementations, the resistance unit 300 may be a passive element with a predetermined resistance value. The resistance unit 300 may connect between the semiconductor unit 100 and an external element (for example, a gate driver or an IC chip) that controls the operation of the semiconductor unit 100. Accordingly, the semiconductor unit 100 may be electrically connected to the external element (for example, the gate driver or the IC chip) that controls the operation of the semiconductor unit 100 through the resistance unit 300. External signals (e.g., a power voltage or a gate voltage, etc.) that control the operation of the semiconductor unit 100 may be applied to the semiconductor unit 100 through the resistance unit 300. In some implementations, the peripheral circuit area PA may refer to an area where the resistance unit 300 is placed.

In the implementations, it has been described that the resistance unit 300 is positioned in the peripheral circuit area PA, but it is not limited thereto. For example, within the peripheral circuit area PA, passive elements such as capacitors or inductors may be positioned, or active elements such as transistors, diodes, or IC (integrated circuit) chips may be positioned. As another example, a temperature sensor, a current divider, a voltage divider, a voltage clipper, a protection element of the semiconductor unit 100, etc. may be positioned within the peripheral circuit area PA.

In some implementations, the peripheral circuit area PA may be positioned spaced apart from the main element area TA. For example, as shown in FIG. 1, the peripheral circuit area PA may be positioned away from the main element area TA in a second direction (a Y direction), but the disclosure is not limited thereto. For example, the peripheral circuit area PA may be positioned away from the main element area TA in a first direction (a X direction), or may surround the side of the main element area TA. Of course, various other changes are possible. In some implementations, a separation structure 160 may be positioned between the peripheral circuit area PA and the main element area TA, but it is not limited thereto.

Further referring to FIG. 2, the main element area TA of the semiconductor device according to some implementations includes a main channel layer 132, a barrier layer 136 placed on the main channel layer 132, a gate electrode 155 positioned on the barrier layer 136, a gate semiconductor layer 152 positioned between the barrier layer 136 and the gate electrode 155, a protective layer 140 positioned on the barrier layer 136, and a source electrode 173 and a drain electrode 175 separated from each other on the main channel layer 132.

The main channel layer 132 is a layer that forms a channel between the source electrode 173 and the drain electrode 175, and a 2-dimensional electron gas (2DEG) 134 may be positioned inside the main channel layer 132. The 2-dimensional electron gas 134 is a charge transport model used in solid physics, and refers to a group of electrons that can move freely in a 2-dimensional (e.g., a x-y planar direction) but cannot move in another dimension (e.g., a z direction) and are tightly bound within a 2-dimensional space. In other words, the 2-dimensional electron gas 134 may exist in a 2-dimensional paper-like form within a 3-dimensional space. This 2-dimensional electron gas 134 mainly appears in a semiconductor heterojunction structure, and may occur at the interface between the channel layer 132 and the barrier layer 136 in the semiconductor device according to some implementations. For example, the 2-dimensional electron gas 134 may be generated in the portion close to the barrier layer 136 within the main channel layer 132.

The main channel layer 132 may include one or more materials selected from Group III-V materials, such as nitrides including Al, Ga, In, B, or combinations thereof. The main channel layer 132 may be composed of a single layer or multiple layers. The main channel layer 132 may be AlₓIn_{y}Ga_{(1-x-y)}N (0≤x≤1, 0≤y≤1, x+y≤1). For example, the main channel layer 132 may be AlN, GaN, InN, InGaN, AlGaN, AlInN, AlInGaN, or a combination thereof. The main channel layer 132 may be a layer with a doped impurity or a layer with a undoped impurity. The thickness of the main channel layer 132 may be about several hundred nm or less.

The main channel layer 132 may be positioned on the substrate 110, and a seed layer 121 and a buffer layer 120 may be positioned between the substrate 110 and the channel layer 132. The substrate 110, the seed layer 121, and the buffer layer 120 are layers that form the main channel layer 132, and may be omitted in some cases. For example, when a substrate made of GaN is used as the main channel layer 132, at least one of the substrate 110, the seed layer 121, and the buffer layer 120 may be omitted. Considering that the price of a substrate made of GaN is relatively high, the main channel layer 132 including GaN may be grown using the substrate 110 made of Si. At this time, as a lattice structure of Si and a lattice structure of GaN are different, it may not be easy to grow the main channel layer 132 directly on the substrate 110. Accordingly, after growing the seed layer 121 and the buffer layer 120 on the substrate 110 first, the main channel layer 132 may be grown on the buffer layer 120. Additionally, at least one of the substrate 110, the seed layer 121, and the buffer layer 120 may be removed from the final structure of the semiconductor device after being used in the manufacturing process.

The substrate 110 may include a semiconductor material. For example, the substrate 110 may include sapphire, Si, SiC, AlN, GaN, or a combination thereof. The substrate 110 may be a silicon on insulator (SOI) substrate. However, the material of the substrate 110 is not limited to this, and any generally-used substrate may be applied. In some cases, the substrate 110 may include an insulating material. For example, after forming first several layers, including the main channel layer 132, on the semiconductor substrate, then the semiconductor substrate may be removed to be replaced with an insulation substrate.

The seed layer 121 may be positioned directly above the substrate 110. However, the disclosure is not limited to the above, and another predetermined layer may be further positioned between the substrate 110 and the seed layer 121. The seed layer 121 is a layer that serves as a seed for growing the buffer layer 120, and may be made of a crystal lattice structure that becomes the seed of the buffer layer 120 . . . . The buffer layer 120 may be positioned directly above the seed layer 121 . . . . However, the disclosure is not limited to the above, and another predetermined layer may be positioned between the seed layer 121 and the buffer layer 120. The seed layer 121 may include one or more materials selected from Group III-V materials, such as nitrides including Al, Ga, In, B, or combinations thereof. The seed layer 121 may be AlₓIn_{y}Ga_{(1-x-y)}N (0≤x≤1, 0≤y≤1, x+y≤1). For example, the seed layer 121 may be AlN, GaN, InN, InGaN, AlGaN, AlInN, AlInGaN, or a combination thereof.

The buffer layer 120 may be positioned above the seed layer 121. The buffer layer 120 may be positioned between the seed layer 121 and the main channel layer 132. The buffer layer 120 may be a layer to alleviate the difference in a lattice constant and a thermal expansion coefficient between the seed layer 121 and the main channel layer 132, or to prevent a parasitic current (a leakage current) from flowing through the main channel layer 132. The buffer layer 120 may include one or more materials selected from Group III-V materials, such as nitrides including Al, Ga, In, B, or combinations thereof. The buffer layer 120 may be AlₓIn_{y}Ga_{(1-x-y)}N (0≤x≤1, 0≤y≤1, x+y≤1). For example, the buffer layer 120 may be AlN, GaN, InN, InGaN, AlGaN, AlInN, AlInGaN, or a combination thereof.

The buffer layer 120 of the semiconductor device according to some implementations includes a superlattice layer 124 positioned above the seed layer 121, and a high resistance layer 126 positioned above the superlattice layer 124. The superlattice layer 124 and the high-resistance layer 126 may be positioned sequentially on the substrate 110.

The superlattice layer 124 may be positioned above the seed layer 121. The superlattice layer 124 may be positioned directly above the seed layer 121. However, the disclosure is not limited to the above, and another predetermined layer may be positioned between the seed layer 121 and the superlattice layer 124. The superlattice layer 124 alleviates the difference in a lattice constant and a thermal expansion coefficient between the substrate 110 and the main channel layer 132, thereby reducing a tensile stress and a compressive stress generated between the substrate 110 and the main channel layer 132, and is a layer to relieve a stress between entire layers formed by a growth in the final structure of the semiconductor device according to some implementations. The superlattice layer 124 may include one or more materials selected from Group III-V materials, such as nitrides including Al, Ga, In, B, or combinations thereof. The superlattice layer 124 may be AlₓIn_{y}Ga_{(1-x-y)}N (0≤x≤1, 0≤y≤1, x+y≤1). For example, the superlattice layer 124 may be AlN, GaN, InN, InGaN, AlGaN, AlInN, AlInGaN, or a combination thereof.

In some implementations, the superlattice layer 124 may be comprised of multiple layers of alternating layers including different materials. For example, the superlattice layer 124 may have a structure in which a layer made of AlGaN and a layer made of AlN are repeatedly stacked

That is, AlGaN/AlN/AlGaN/AlN/AlGaN/AlN may be sequentially stacked to form a superlattice layer. The number of AlGaN layers and AlN that make up the superlattice layer 124 may be changed in various ways, and the material that makes up the superlattice layer 124 may be changed in various ways. As another example, the superlattice layer may have a structure in which a layer made of AlGaN and a layer made of GaN are repeatedly stacked. That is, AlGaN/GaN/AlGaN/GaN/AlGaN/GaN may be sequentially stacked to form a superlattice layer. In some implementations, when the superlattice layer 124 includes GaN, InN, AlGaN, AlInN, InGaN, AlN, AlInGaN or a combination thereof, the superlattice layer 124 may have an N-type semiconductor characteristic in which the concentration of electrons is greater than the concentration of holes, but it is not limited thereto.

The high resistance layer 126 may be positioned above the superlattice layer 124. The high resistance layer 126 may be positioned directly above the superlattice layer 124. However, the disclosure is not limited to the above, and other predetermined layers may be positioned between the superlattice layer 124 and the high resistance layer 126. The high resistance layer 126 may be positioned between the superlattice layer 124 and the main channel layer 132. The high resistance layer 126 is a layer to prevent the semiconductor device according to some implementations from being degraded by preventing a leakage current from flowing through the main channel layer 132. The high resistance layer 126 may be made of a material with low conductivity so that it may be electrically insulated between the substrate 110 and the main channel layer 132. The high resistance layer may include one or more materials selected from Group III-V materials, such as nitrides including Al, Ga, In, B, or combinations thereof. The high resistance layer 126 may be AlₓIn_{y}Ga_{(1-x-y)}N (0≤x≤1, 0≤y≤1, x+y≤1). For example, the high resistance layer 126 may be AlN, GaN, InN, InGaN, AlGaN, AlInN, AlInGaN, or a combination thereof. The high resistance layer 126 may be made of a single layer or multiple layers. In some implementations, when the high resistance layer 126 includes GaN, InN, AlGaN, AlInN, InGaN, AlN, AlInGaN or a combination thereof, the high resistance layer 126 may have an N-type semiconductor characteristic in which the concentration of electrons is greater than the concentration of holes, but it is not limited thereto.

The barrier layer 136 may be positioned above the main channel layer 132. The barrier layer 136 may be positioned directly above the main channel layer 132. However, the disclosure is not limited to the above, and another predetermined layer may be positioned between the main channel layer 132 and the barrier layer 136. The area of the main channel layer 132 that overlaps the barrier layer 136 may be a first drift area DTR1. The first drift area DTR1 may be positioned between the source electrode 173 and the drain electrode 175. The first drift area DTR1 may refer to the area to which the carrier moves when a potential difference occurs between the source electrode 173 and the drain electrode 175.

The semiconductor device according to some implementations may be turned on/off depending on whether a voltage is applied to the gate electrode 155 and/or the magnitude of the voltage applied to the gate electrode 155, and accordingly, the movement of the carrier may occur in the first drift area DTR1 or be blocked.

The barrier layer 136 may include one or more materials selected from Group III-V materials, such as nitrides including Al, Ga, In, B, or combinations thereof. The barrier layer 136 may be AlₓIn_{y}Ga_{(1-x-y)}N (0≤x≤1, 0≤y≤1, x+y≤1). For example, the barrier layer 136 may be AlN, GaN, InN, InGaN, AlGaN, AlInN, AlInGaN, or a combination thereof. The energy band gap of the barrier layer 136 may be adjusted by a composition ratio of Al and/or In. The barrier layer 136 may be doped with a predetermined impurity. At this time, the impurity doped in the barrier layer 136 may be a P-type dopant that may provide a hole. For example, the impurity doped in the barrier layer 136 may be magnesium (Mg). By increasing or decreasing the impurity doping concentration of the barrier layer 136, a threshold voltage, an on-resistance, etc. of the semiconductor device according to some implementations may be adjusted.

The barrier layer 136 may include a semiconductor material with different characteristics from the main channel layer 132. The barrier layer 136 may differ from the main channel layer 132 in at least one of a polarization characteristic, an energy band gap, or a lattice constant. For example, the barrier layer 136 may include a material having a different energy band gap than the main channel layer 132. At this time, the barrier layer 136 may have a higher energy band gap than the main channel layer 132 and may have a higher electrical polarization rate than the main channel layer 132. This barrier layer 136 may cause a 2-dimensional electron gas 134 in the main channel layer 132, which has a relatively low electrical polarization rate. In this regard, the barrier layer 136 may also be called a channel supply layer or a 2-dimensional electron gas supply layer. The 2-dimensional electron gas 134 may be formed within a portion of the main channel layer 132 positioned below the interface between the main channel layer 132 and the barrier layer 136. The 2-dimensional electron gas 134 may have a very high electron mobility.

The barrier layer 136 may be composed of a single layer or multiple layers. If the barrier layer 136 is made of multiple layers, the energy band gap of the material of each layer constituting the multiple layers may be different. At this time, the multiple layers constituting the barrier layer 136 may be arranged so that the energy band gap increases as it approaches the main channel layer 132.

The gate electrode 155 may be positioned on the barrier layer 136. The gate electrode 155 may overlap a portion of the barrier layer 136 in the vertical direction (for example, the thickness direction of the main channel layer 132). The gate electrode 155 may overlap a portion of the first drift area DTR1 of the main channel layer 132 in the vertical direction (e.g., the thickness direction of the main channel layer 132). The gate electrode 155 may be positioned between the source electrode 173 and the drain electrode 175. The gate electrode 155 may be separated from the source electrode 173 and the drain electrode 175. For example, the gate electrode 155 may be positioned closer to the source electrode 173 than the drain electrode 175. In other words, the separation distance between the gate electrode 155 and the source electrode 173 may be smaller than the separation distance between the gate electrode 155 and the drain electrode 175, but it is not limited thereto.

The gate electrode 155 may include a conductive material. For example, the gate electrode 155 may include a metal, a metal alloy, a conductive metal nitride, a metal silicide, a doped semiconductor material, a conductive metal oxide, or a conductive metal oxynitride. For example, the gate electrode 155 may include titanium nitride (TIN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonizationnitride (TiAlC—N), titanium aluminum carbide (TiAlC), titanium carbide (TIC), tantalum carbonizationnitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or combination thereof, but it is not thereto. The gate electrode 155 may be made of a single layer or multiple layers.

The gate semiconductor layer 152 may be positioned between the barrier layer 136 and the gate electrode 155. That is, the gate semiconductor layer 152 may be positioned on the barrier layer 136, and the gate electrode 155 may be positioned on the gate semiconductor layer 152. The gate electrode 155 may be in Schottky contact or ohmic contact with the gate semiconductor layer 152. The gate semiconductor layer 152 may overlap the gate electrode 155 in the vertical direction (for example, the thickness direction of the main channel layer 132). At this time, the gate semiconductor layer 152 may completely overlap with the gate electrode 155 in the vertical direction (for example, the thickness direction of the main channel layer 132), and the upper surface of the gate semiconductor layer 152 may be entirely covered by the gate electrode 155. That is, the gate semiconductor layer 152 may have substantially the same planar shape as the gate electrode 155. However, it is not limited thereto, the gate electrode 155 may be positioned to cover at least a part of the gate semiconductor layer 152.

The gate semiconductor layer 152 may be positioned between the source electrode 173 and the drain electrode 175. The gate semiconductor layer 152 may be separated from the source electrode 173 and the drain electrode 175. The gate semiconductor layer 152 may be positioned closer to the source electrode 173 than the drain electrode 175. In other words, the separation distance between the gate semiconductor layer 152 and the source electrode 173 may be smaller than the separation distance between the gate semiconductor layer 152 and the drain electrode 175, but it is not limited thereto.

In some implementations, the gate semiconductor layer 152 may overlap the gate electrode 155 in the vertical direction (e.g., the thickness direction of the main channel layer 132). For example, the gate semiconductor layer 152 may completely overlap with the gate electrode 155 in the vertical direction (e.g., the thickness direction of the main channel layer 132). That is, the side of the gate semiconductor layer 152 may be aligned with the side of the gate electrode 155. However, it is not limited thereto, the gate semiconductor layer 152 may partially overlap the gate electrode 155.

The gate semiconductor layer 152 may include one or more materials selected from Group III-V materials, such as nitrides including Al, Ga, In, B, or combinations thereof. The gate semiconductor layer 152 may be AlₓIn_{y}Ga_{1-x-y}N (0≤x≤1, 0≤y≤1, x+y≤1). For example, the gate semiconductor layer 152 may include AlN, GaN, InN, InGaN, AlGaN, AlInN, AlInGaN, or a combination thereof. The gate semiconductor layer 152 may include a material having a different energy band gap from the barrier layer 136. For example, the gate semiconductor layer 152 may include GaN, and the barrier layer 136 may include AlGaN. The gate semiconductor layer 152 may be doped with a predetermined impurity. At this time, the impurity doped in the gate semiconductor layer 152 may be a P-type dopant that can provide a hole. For example, the gate semiconductor layer 152 may include GaN doped with a P-type impurity. That is, the gate semiconductor layer 152 may be made of a p-GaN layer. However, the disclosure is not limited to the above, and the gate semiconductor layer 152 may be a p-AlGaN layer. The impurity doped in the gate semiconductor layer 152 may be magnesium (Mg). At this time, when the doped impurity (e.g., magnesium) within the gate semiconductor layer 152 is combined with an adjacent predetermined element, the hole concentration within the gate semiconductor layer 152 may be reduced, and the characteristics of the semiconductor device may be degraded accordingly. The gate semiconductor layer 152 may be made of a single layer or multiple layers.

A depletion region DPR may be formed within the channel layer 132 by the gate semiconductor layer 152. The depletion region DPR may be positioned within the drift region DTR and may have a narrower width than the drift region DTR. As the gate semiconductor layer 152, which has the different energy band gap from that of the barrier layer 136, is positioned on the barrier layer 136, the level of the energy band of the portion of the barrier layer 136 that overlaps the gate semiconductor layer 152 may increase. Accordingly, the depletion region DPR may be formed in the region of the main channel layer 132 that overlaps the gate semiconductor layer 152. The depletion region DPR may be a region in the channel path of the channel layer 132 in which the 2-dimensional electron gas 134 is not formed or has a lower electron concentration than the remaining regions. In other words, the depletion region DPR may mean a region where the flow of the 2-dimensional electron gas 134 is disconnected within the drift region DTR. As the depletion region DPR occurs, a current does not flow between the source electrode 173 and the drain electrode 175, and the channel path may be blocked. Accordingly, the semiconductor device according to some implementations may have a normally off characteristic.

That is, the semiconductor device according to some implementations may be a normally off high electron mobility transistor (HEMT). As shown in FIG. 2, In a normal state in which no voltage is applied to the gate electrode 155, the depletion region DPR exists, and the semiconductor device according to some implementations may be in an off state. As shown in FIG. 3, when a voltage higher than a threshold voltage is applied to the gate electrode 155, the depletion region DPR disappears, and the 2-dimensional electron gas 134 within the drift region DTR is not disconnected and may be connected. That is, the 2-dimensional electron gas 134 may be formed throughout the channel path between the source electrode 173 and the drain electrode 175, and the semiconductor device according to some implementations may be in an on state. In summary, the semiconductor device according to some implementations may include the semiconductor layers with different electrical polarization characteristics, the semiconductor layer with the relatively high polarization rate may induce the 2-dimensional electron gas 134 in another semiconductor layer heterogeneously jointed thereto. This 2-dimensional electron gas 134 may be used as a channel between the source electrode 173 and the drain electrode 175, and the connection or disconnection of the flow of this 2-dimensional electron gas 134 may be controlled by the bias voltage applied to the gate electrode 155. In the gate off state, the flow of the 2-dimensional electron gas 134 is blocked, so a current may not flow between the source electrode 173 and the drain electrode 175. As the flow of the 2-dimensional electron gas 134 continues in the gate on state, a current may flow between the source electrode 173 and the drain electrode 175.

In the above, the case where the semiconductor device according to some implementations is a normally off high electron mobility transistor has been described, but the disclosure is not limited thereto. For example, the semiconductor device according to some implementations may be a normally-on high electron mobility transistor. In the case of the normally-on high electron mobility transistor, the gate semiconductor layer 152 may be omitted, and thus the gate electrode 155 may be positioned directly above the barrier layer 136. That is, the gate electrode 155 may be in contact with the barrier layer 136. In this structure, the 2-dimensional electron gas 134 may be used as a channel without a voltage being applied to the gate electrode 155, and a current flow may occur between the source electrode 173 and the drain electrode 175. Additionally, when a negative voltage is applied to the gate electrode 155, a depletion area (DPR) in which the flow of the 2-dimensional electron gas 134 is cut off may occur at the lower portion of the gate electrode 155.

The previously described seed layer 121, superlattice layer 124, high resistance layer 126, main channel layer 132, barrier layer 136, and gate semiconductor layer 152 may be sequentially stacked on the substrate 110. In the semiconductor device according to some implementations, at least one of the seed layer 121, the superlattice layer 124, the high resistance layer 126, the main channel layer 132, the barrier layer 136, and the gate semiconductor layer 152 may be omitted. The seed layer 121, the superlattice layer 124, the high resistance layer 126, the main channel layer 132, the barrier layer 136, and the gate semiconductor layer 152 may be made of the same-based semiconductor material, and by considering the role of each layer and the performance required for the semiconductor device, etc., a material composition ratio of each layer may be different.

A protective layer 140 may be positioned above the barrier layer 136 and the gate electrode 155. The protective layer 140 may cover the upper and side surfaces of the gate electrode 155 and the side surface of the gate semiconductor layer 152. The lower surface of the protective layer 140 may be in contact with the barrier layer 136 and the gate electrode 155. Accordingly, the barrier layer 136, the gate semiconductor layer 152, and the gate electrode 155 may be protected by the protective layer 140. However, it is not limited thereto, the gate electrode 155 may penetrate the protective layer 140 and be connected to the gate semiconductor layer 152, and the protective layer 140 may not cover the upper surface of the gate electrode 155. Alternatively, the lower surface of protective layer 140 may be in contact with the gate semiconductor layer 152. The protective layer 140 may include an insulating material. For example, the protective layer 140 may include oxide such as SiO₂ or Al₂O₃. As another example, the protective layer 140 may include nitride such as SiN or oxynitride such as SiON.

In FIG. 2 and FIG. 3, the protective layer 140 is shown as being made of a single layer, but it is not limited thereto, the protective layer 140 may be made of multiple layers including different materials.

The source electrode 173 and the drain electrode 175 may be positioned above the main channel layer 132. The source electrode 173 and the drain electrode 175 may be in direct contact with the main channel layer 132 and electrically connected to the main channel layer 132. The source electrode 173 and the drain electrode 175 may be spaced apart from each other, and the gate electrode 155 and the gate semiconductor layer 152 may be positioned between the source electrode 173 and the drain electrode 175. The gate electrode 155 and the gate semiconductor layer 152 may be separated from the source electrode 173 and the drain electrode 175. For example, the source electrode 173 may be electrically connected to the main channel layer 132 on one side of the gate electrode 155, and the drain electrode 175 may be electrically connected to the channel layer 132 on the other side of the gate electrode 155. The source electrode 173 and the drain electrode 175 may be positioned outside the drift region DTR of the main channel layer 132. The interface between the source electrode 173 and the channel layer 132 may be one edge of the drift region DTR. Likewise, the interface between the drain electrode 175 and the channel layer 132 may be the other edge of the drift region DTR.

However, it is not limited thereto, and the source electrode 173 and the drain electrode 175 may not be positioned on the exterior side of the first drift area DTR1 of the main channel layer 132. That is, the main channel layer 132 may not be recessed, and the source electrode 173 and the drain electrode 175 may be positioned on the upper surface of the main channel layer 132. The bottom surface of the source electrode 173 and the drain electrode 175 may be in contact with the top surface of the main channel layer 132. The portion of the main channel layer 132 in contact with the source electrode 173 and the drain electrode 175 may be doped with high concentration. At this time, the carrier passing through the two-dimensional electron gas 134 may pass through the portion of the main channel layer 132 doped at high concentration, that is, the upper part of the two-dimensional electron gas 134, and be transferred to the source electrode 173 and the drain electrode 175. The source electrode 173 and the drain electrode 175 may be not in direct contact with the two-dimensional electron gas 134 in the horizontal direction. Here, the horizontal direction may mean a direction parallel to the upper surface of the main channel layer 132 or the barrier layer 136.

Specifically, a trench that penetrates the lower protection layer 180 and the barrier layer 136 and recesses the upper surface of the main channel layer 132 may be positioned on both sides of the gate electrode 155 to be spaced apart from each other. The source electrode 173 and the drain electrode 175 may be positioned within the trench positioned on both sides of the gate electrode 155, respectively. The source electrode 173 and the drain electrode 175 may be formed to fill the trench. Within the trench, the source electrode 173 and the drain electrode 175 may be in contact with the main channel layer 132 and the barrier layer 136. The main channel layer 132 may form the bottom surface and the sidewall of the trench, and the barrier layer 136 may form the sidewall of the trench. Accordingly, the source electrode 173 and the drain electrode 175 may be in contact with the upper and side surfaces of the main channel layer 132. Additionally, the source electrode 173 and the drain electrode 175 may be in contact with the side of the barrier layer 136. That is, the source electrode 173 and the drain electrode 175 may cover the sides of the main channel layer 132 and the barrier layer 136.

In some implementations, the source electrode 173 and the drain electrode 175 may cover at least a portion of the side of protective layer 140. For example, the source electrode 173 and the drain electrode 175 may cover the side of the protective layer 140. The upper surfaces of the source electrode 173 and the drain electrode 175 may be protruded from the upper surface of the protective layer 140. Additionally, at least one of the source electrode 173 and the drain electrode 175 may cover at least a portion of the upper surface of the protective layer 140. However, it is not limited thereto, the source electrode 173 and the drain electrode 175 may cover at least part of the side of the protective layer 140 and may not cover the remaining part of the side of the protective layer 140. In this case, the remaining part of the protective layer 140 may be positioned on the upper surfaces of the source electrode 173 and the drain electrode 175.

The source electrode 173 and the drain electrode 175 may include a conductive material. For example, the source electrode 173 and the drain electrode 175 may include a metal, a metal alloy, a conductive metal nitride, a metal silicide, a doped semiconductor material, a conductive metal oxide, or a conductive metal oxynitride. For example, the source electrode 173 and the drain electrode 175 may include titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonizationnitride (TiAlC—N), titanium aluminum carbide (TiAlC), titanium carbide (TIC), tantalum carbonizationnitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or combination thereof, but it is not limited thereto. The source electrode 173 and the drain electrode 175 may be made of a single layer or multiple layers. The source electrode 173 and the drain electrode 175 may be in ohmic contact with the main channel layer 132. The region in contact with the source electrode 173 and the drain electrode 175 within the main channel layer 132 may be doped at a relatively high concentration compared to other regions.

In FIG. 1 to FIG. 3, the semiconductor device according to some implementations is shown as including a pair of source electrode 173 and drain electrode 175, but the number of the source electrode 173 and the drain electrode 175 is not limited thereto. For example, the source electrode 173 may include a plurality of source electrodes 173 sequentially stacked in the vertical direction (e.g., the thickness direction of the main channel layer 132) on the main channel layer 132, and the drain electrode 175 may include a plurality of drain electrodes 175 sequentially stacked on the main channel layer 132 in the vertical direction (e.g., the thickness direction of the main channel layer 132). Alternatively, each of the source electrode 173 and the drain electrode 175 may include three or more layers.

The semiconductor device according to some implementations may further include a field dispersed layer covering at least a portion of the protective layer 140.

The field dispersed layer may be positioned between the source electrode 173 and the drain electrode 175. The field dispersed layer may cover the gate electrode 155. The field dispersed layer may overlap the gate electrode 155 in the vertical direction (for example, the thickness direction of the main channel layer 132). The field dispersed layer may be electrically connected to the source electrode 173. For example, the field dispersed layer may be connected to the source electrode 173. The field dispersed layer may include the same material as the source electrode 173 and may be positioned in the same layer as the source electrode 173. The field dispersed layer may be formed simultaneously in the same process as the source electrode 173. That is, the boundary between the field dispersed layer and the source electrode 173 is not clear, and the field dispersed layer may be formed integrally with the source electrode 173. However, it is not limited thereto, and the field dispersed layer may be a separate component from the source electrode 173. Additionally, the field dispersed layer may be positioned in a different layer from the source electrode 173 and may be formed in a different process.

The field dispersed layer may serve to disperse the electric field concentrated around the gate electrode 155. Specifically, in the gate off state, the 2-dimensional electron gas 134 may be positioned with very high concentration in the part of the main channel layer 132 positioned between the gate electrode 155 and the source electrode 173 and in the part of the main channel layer 132 positioned between the gate electrode 155 and the drain electrode 175. In this case, an electric field may be concentrated on the gate electrode 155 or the gate semiconductor layer 152. Meanwhile, the gate electrode 155 and the gate semiconductor layer 152 are vulnerable to electric fields, so when the electric fields are concentrated, a leakage current may increase and a breakdown voltage may decrease. At this time, the electric field concentrated around the gate electrode 155 or the gate semiconductor layer 152 is dispersed by the field dispersed layer, so the leakage current may be reduced and the breakdown voltage may be increased.

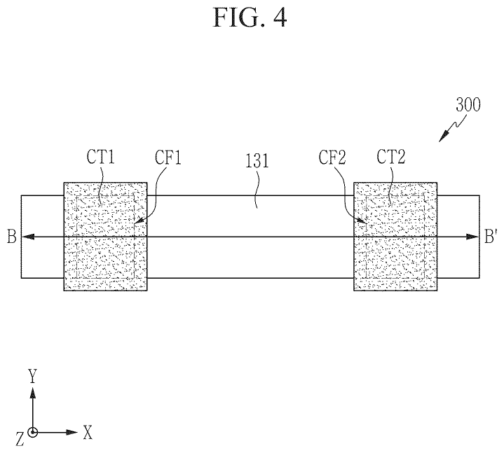

Hereinafter, the resistance element of the semiconductor device according to some implementations will be described with further reference to FIG. 4 to FIG. 6.

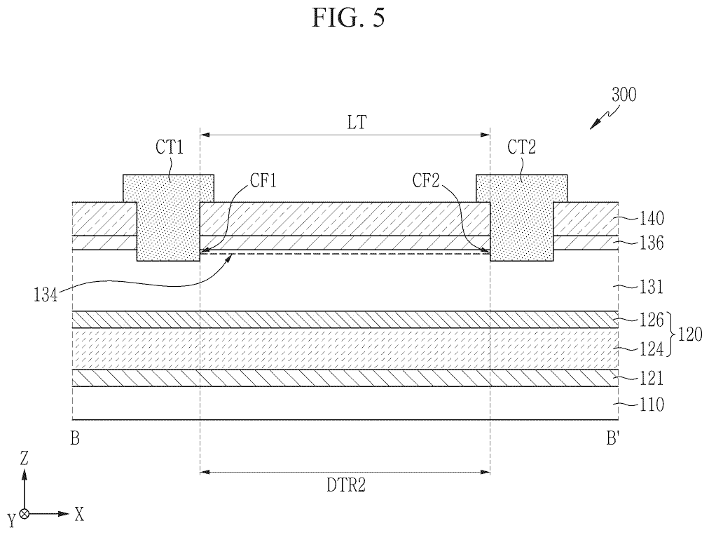

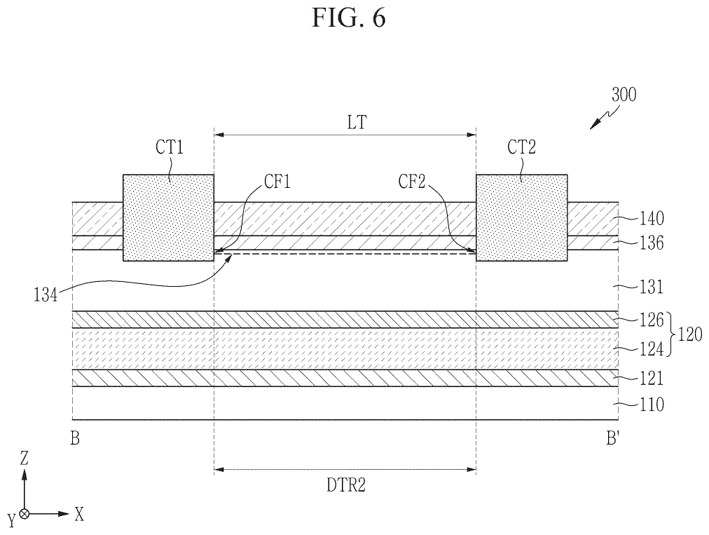

FIG. 4 is a top plan view showing a resistance unit of a semiconductor device according to some implementations. FIG. 5 is a cross-sectional view cut along a line B-B′ in FIG. 4. FIG. 6 is a cross-sectional view showing a semiconductor device according to some implementations and corresponding to a line B-B′ of FIG. 4.

First, referring to FIG. 4 and FIG. 5, a resistance unit 300 positioned in the peripheral circuit area PA of the semiconductor device according to some implementations includes a channel pattern 131 positioned on a substrate 110, a barrier layer 136 positioned on the channel pattern 131, and a first contact electrode CT1 and a second contact electrode CT2 positioned on the channel pattern 131.

The channel pattern 131 may extend in one direction on the substrate 110. For example, the channel pattern 131 may extend along the first direction (the X direction). The channel pattern 131 is a layer that forms a channel between the first contact electrode CT1 and the second contact electrode CT2, and a 2-dimensional electron gas (2DEG) 134 may be positioned inside the channel pattern 131. The 2-dimensional electron gas 134 is a charge transport model used in solid physics, and refers to a group of electrons that can move freely in a 2-dimensional (e.g., a x-y planar direction) but cannot move in another dimension (e.g., a z direction) and are tightly bound within a 2-dimensional space. In other words, the 2-dimensional electron gas 134 may exist in a 2-dimensional paper-like form within a 3-dimensional space. This 2-dimensional electron gas 134 mainly appears in a semiconductor heterojunction structure, and may occur at the interface between the channel pattern 131 and the barrier layer 136 in the semiconductor device according to some implementations. For example, the 2-dimensional electron gas 134 may be generated in the portion close to the barrier layer 136 within the main channel pattern 131.

In some implementations, the channel pattern 131 may be integrally formed by the same process as the main channel layer 132 of the main element area TA. The lower surface of the channel pattern 131 may be positioned at the same level as the lower surface of main channel layer 132, and the upper surface of the channel pattern 131 may be positioned at the same level as the upper surface of the main channel layer 132. That is, the lower surface of the channel pattern 131 may be positioned at the same distance from the lower surface of the main channel layer 132 and the upper surface of the substrate 110. Additionally, the upper surface of the channel pattern 131 may be positioned at the same distance as the upper surface of the main channel layer 132. The channel pattern 131 may refer to the main channel layer 132 portion located in the peripheral circuit area PA.

In some implementations, the channel pattern 131 may include the same material as the main channel layer 132 positioned in the main element area TA. For example, the channel pattern 131 may include one or more materials selected from Group III-V materials, such as nitrides including Al, Ga, In, B, or combinations thereof. The channel pattern 131 may be composed of a single layer or multiple layers. The channel pattern 131 may be AlₓIn_{y}Ga_{(1-x-y)}N (0≤x≤1, 0≤y≤1, x+y≤1). For example, the channel pattern 131 may be AlN, GaN, InN, InGaN, AlGaN, AlInN, AlInGaN, or a combination thereof. The thickness of the channel pattern 131 along the third direction (the Z direction) may be substantially the same as the thickness of the main channel layer 132 along the third direction (the Z direction), but the disclosure is not limited thereto.

The channel pattern 131 may be positioned on the substrate 110, and the seed layer 121 and the buffer layer 120 may be positioned between the substrate 110 and the channel pattern 131. The substrate 110, the seed layer 121, and the buffer layer 120 are layers that form the channel pattern 131, and may be omitted in some cases. In some implementations, the substrate 110, the seed layer 121, and the buffer layer 120 positioned in the peripheral circuit area PA may be integrally formed by the same process as the substrate 110, the seed layer 121, and the buffer layer 120 positioned in the main element area TA, respectively.

The barrier layer 136 may be positioned above the channel pattern 131. The barrier layer 136 may be positioned directly above the channel pattern 131. However, it is not limited thereto, and another predetermined layer may be further positioned between the channel pattern 131 and the barrier layer 136. The area of the channel pattern 131 that overlaps the barrier layer 136 may be the second drift area DTR2. The second drift area DTR2 may be positioned between the first contact electrode CT1 and the second contact electrode CT2. The second drift area DTR2 may refer to the area to which the carrier moves when a potential difference occurs between the first contact electrode CT1 and the second contact electrode CT2.

Specifically, as the barrier layer 136 is different from the channel pattern 131 in at least one of the polarization characteristic, the energy band gap, or the lattice constant, the 2-dimensional electron gas 134 may be induced in the channel pattern 131 with a relatively low electrical polarization rate by the barrier layer 136. In this regard, the barrier layer 136 may also be called a channel supply layer or a 2-dimensional electron gas supply layer. The 2-dimensional electron gas 134 may be formed within a portion of the channel pattern 131positioned below the interface between the channel pattern 131 and the barrier layer 136. The 2-dimensional electron gas 134 may have a very high electron mobility.

In some implementations, the second drift area DTR2 may have a resistance component. In other words, the second drift area DTR2 may function as a resistance with a predetermined resistance value. Accordingly, when a potential difference is generated between the second contact electrode CT2 and the first contact electrode CT1 and a current flows into the second drift area DTR2, a voltage drop may occur between the second contact electrode CT2 and the first contact electrode CT1. In other words, the area of the channel pattern 131 that overlaps the barrier layer 136 may have a predetermined resistance value. The area of the channel pattern 131 that overlaps the barrier layer 136 between the first contact electrode CT1 and the second contact electrode CT2 may function as a resistance component.

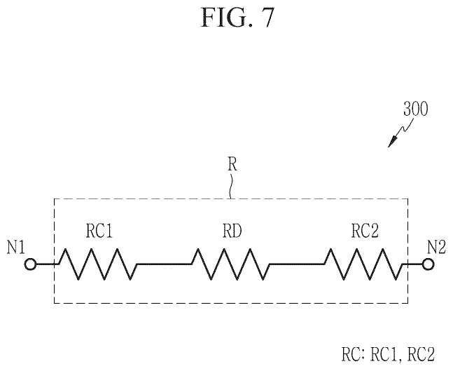

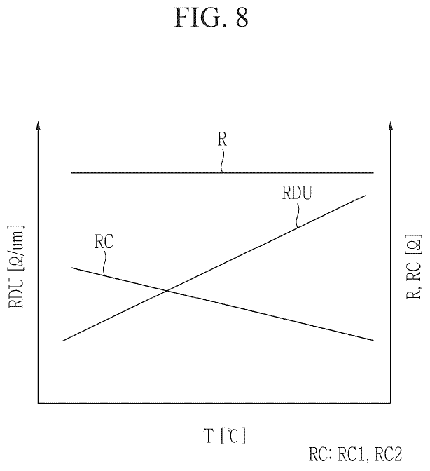

At this time, a resistance RD (RD in FIG. 7) of the second drift area DTR2 may have different values depending on the temperature. For example, the resistance RD (RD in FIG. 7) of the second drift area DTR2 may increase as the temperature increases. In other words, the resistance RD of the second drift area DTR2 (RD in FIG. 7) may have a positive sign temperature coefficient of resistance (TCR). The explanation thereof is described later with reference to FIG. 7 and FIG. 8.

In some implementations, the second drift area DTR2 may extend in the first direction (the X direction). At this time, the length LT of the second drift area DTR2 along the first direction (the X direction) may be 1 μm to 10 μm. The length LT of the second drift area DTR2 along the first direction (the X direction) may be 3 μm to 4 μm. Here, the length LT of the second drift area DTR2 along the first direction (the X direction) may refer to the length along the first direction (X direction) between the first contact interface CF1 of the channel pattern 131 in contact with the first contact electrode CT1 and the second contact interface CF2 of the channel pattern 131 in contact with the second contact electrode CT2. That is, in some implementations, the length of the channel pattern 131 between the first contact interface CF1 and the second contact interface CF2 along the first direction (the X direction) may be 1 μm to 10 μm. In addition, the length of the channel pattern 131 between the first contact interface CF1 and the second contact interface CF2 in the first direction (the X direction) may be 3 μm to 4 μm. In this range, the resistance (R in FIG. 7) of the resistance unit 300 of the semiconductor device according to some implementations may have a constant value without the relationship to the temperature. This is described with reference to FIG. 7 and FIG. 8 later.

The protective layer 140 may be positioned above the barrier layer 136. The lower surface of the protective layer 140 may be in contact with the barrier layer 136. In some implementations, the protective layer 140 may be integrally formed by the same process as the protective layer 140 of the main element area TA. That is, the protective layer 140 may be positioned above the barrier layer 136 of the main element area TA and the barrier layer 136 of the peripheral circuit area PA.

The first contact electrode CT1 and the second contact electrode CT2 may be positioned on the channel pattern 131. The first contact electrode CT1 and the second contact electrode CT2 may be spaced apart from each other. For example, the first contact electrode CT1 and the second contact electrode CT2 may be spaced apart from each other in the elongation direction of the channel pattern 131. That is, the first contact electrode CT1 and the second contact electrode CT2 may be spaced apart from each other in the first direction (the X direction). The first contact electrode CT1 and the second contact electrode CT2 may be positioned outside the second drift area DTR2 of the channel pattern 131. The interface between the first contact electrode CT1 and the channel pattern 131 may be one edge of the second drift area DTR2. Likewise, the interface between the second contact electrode CT2 and the channel pattern 131 may be the other edge of the second drift area DTR2.

In some implementations, the first contact electrode CT1 and the second contact electrode CT2 may be positioned within a space where at least a portion of the channel pattern 131 is recessed. The first contact electrode CT1 and the second contact electrode CT2 may penetrate the barrier layer 136 and be in contact with the side of the channel pattern 131. The first contact electrode CT1 and the second contact electrode CT2 may be in contact with the side of the second drift area DTR2. The first contact electrode CT1 and the second contact electrode CT2 may be electrically connected to the second drift area DTR2. However, it is not limited thereto, and the first contact electrode CT1 and the second contact electrode CT2 may not be positioned on the exterior side of the second drift area DTR2 of the channel pattern 131. That is, the channel pattern 131 may not be recessed, and the first contact electrode CT1 and the second contact electrode CT2 may be positioned on the upper surface of the channel pattern 131. In this case, the bottom surfaces of the first contact electrode CT1 and the second contact electrode CT2 may be in contact with the upper surface of the channel pattern 131.

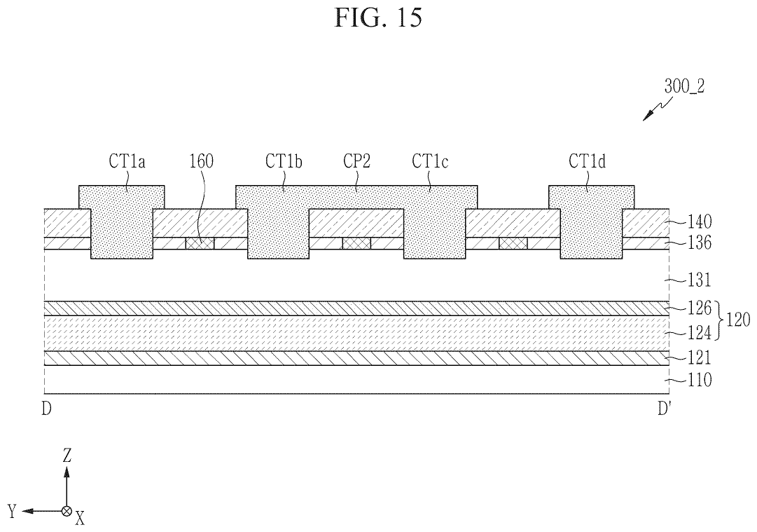

In some implementations, the maximum width of the first contact electrode CT1 and the second contact electrode CT2 along the second direction (the Y direction) may be greater than the width of the channel pattern 131 along the second direction (the Y direction). In detail, as shown in FIG. 4, the width of the portion of the first contact electrode CT1 and the portion of the second contact electrode CT2 positioned within the space where at least a portion of the channel pattern 131 is recessed along the second direction (the Y direction) may be substantially the same as the width of channel pattern 131 along the second direction (the Y direction), and the width of the portion of the first contact electrode CT1 and the portion of the second contact electrode CT2 protruded from the upper surface of the channel pattern 131 along the second direction (the Y direction) may be larger than the width of the channel pattern 131 along the second direction (the Y direction). However, it is not limited thereto, the maximum width of first contact electrode CT1 and the second contact electrode CT2 along the second direction (the Y direction) may be smaller than or substantially the same as the width of channel pattern 131 along the second direction (the Y direction). This is described with reference to FIG. 14 and FIG. 15 later.

In some implementations, the first contact electrode CT1 and the second contact electrode CT2 may be in ohmic contact with the channel pattern 131. At this time, the first contact interface CF1 between the first contact electrode CT1 and the second drift area DTR2, and the second contact interface CF2 between the second contact electrode CT2 and the second drift area DTR2 may have a resistance component. Specifically, in the process where the carrier passing through the 2-dimensional electron gas 134 passes through at least part of the channel pattern 131, that is, the upper part of the 2-dimensional electron gas 134, and is transferred to the first contact electrode CT1 and the second contact electrode CT2, the first contact interface CF1 between first contact electrode CT1 and second drift area DTR2, and the second contact interface CF2 between the second contact electrode CT2 and the second drift area DTR2 may have a predetermined resistance value.

That is, the first contact interface CF1 and the second contact interface CF2 may function as resistances with predetermined resistance values. Accordingly, when a potential difference is formed between the second contact electrode CT2 and the first contact electrode CT1 and a current flows into the second drift area DTR2, a voltage drop may occur at the first contact interface CF1 and the second contact interface CF2. At this time, a first contact resistance of the first contact interface CF1 (RC1 in FIG. 7) and a second contact resistance of the second contact interface CF2 (RC2 in FIG. 7) may have different values depending on the temperature. For example, the first contact resistance of the first contact interface CF1 (RC1 in FIG. 7) and the second contact resistance of the second contact interface CF2 (RC2 in FIG. 7) may decrease as the temperature increases. That is, the first contact resistance of the first contact interface CF1 (RC1 in FIG. 7) and the second contact resistance of the second contact interface CF2 (RC2 in FIG. 7) may have a temperature resistance coefficient (TCR) of a negative sign. This is described with reference to FIG. 7 and FIG. 8 later.

In some implementations, the first contact electrode CT1 and the second contact electrode CT2 may cover at least a portion of the side of the protective layer 140. For example, the first contact electrode CT1 and the second contact electrode CT2 may cover the side of the protective layer 140. The upper surface of the first contact electrode CT1 and the second contact electrode CT2 may be protruded from the upper surface of the protective layer 140.

At least one of the first contact electrode CT1 and the second contact electrode CT2 may cover at least a portion of the upper surface of the protective layer 140. For example, as shown in FIG. 5, the first contact electrode CT1 and the second contact electrode CT2 may be protruded in the first direction (the X direction) to cover at least a portion of the upper surface of the protective layer 140. However, it is not limited thereto, as another example, as shown in FIG. 6, the first contact electrode CT1 and the second contact electrode CT2 may not cover the upper surface of the protective layer 140. As another example, the first contact electrode CT1 and the second contact electrode CT2 may cover at least part of the side surface of the protective layer 140 and may not cover the remaining part of the side surface of the protective layer 140. In this case, the remaining part of the protective layer 140 may be positioned on the upper surfaces of the first contact electrode CT1 and the second contact electrode CT2.

The first contact electrode CT1 and the second contact electrode CT2 may include a conductive material. The first contact electrode CT1 and the second contact electrode CT2 may include the same material as the source electrode 173 and the drain electrode 175. The first contact electrode CT1 and the second contact electrode CT2 may be formed by the same process as the source electrode 173 and the drain electrode 175. For example, the first contact electrode CT1 and the second contact electrode CT2 may include a metal, a metal alloy, a conductive metal nitride, a metal silicide, a doped semiconductor material, a conductive metal oxide, or a conductive metal oxynitride. For example, the first contact electrode CT1 and the second contact electrode CT2 may include titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonizationnitride (TiAlC—N), titanium aluminum carbide (TiAlC), titanium carbide (TIC), tantalum carbonizationnitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or combination thereof, but it is not thereto. The first contact electrode CT1 and the second contact electrode CT2 may be made of a single layer or multiple layers. The first contact electrode CT1 and the second contact electrode CT2 may be in ohmic contact with the channel pattern 131. Within the channel pattern 131, the area in contact with the first contact electrode CT1 and the second contact electrode CT2 may be doped with a relatively high concentration compared to other areas, but it is not limited thereto.

In some implementations, the resistance unit 300 may be separated from the semiconductor unit 100 by a separation structure 160. That is, the resistance unit 300 may be separated from the semiconductor unit 100 by the separation structure 160. The separation structure 160 may penetrate the barrier layer 136 and recess at least a portion of the channel pattern 131 of the resistance unit 300. Accordingly, the second drift area DTR2 of the resistance unit 300 may be electrically insulated with the semiconductor unit 100. However, it is not limited thereto, for example, the resistance unit 300 and the semiconductor unit 100 may be separated by a trench penetrating at least part of the channel pattern 131 and/or the main channel layer 132.

In one embodiment, the separation structure 160 may be formed by forming the barrier layer 136 on the main channel layer 132 and the channel pattern 131 and performing an ion implant process within the barrier layer 136 positioned between the semiconductor unit 100 and the resistance unit 300. However, it is not limited thereto, the separation structure 160 may be formed by forming a barrier layer 136 on the main channel layer 132 and the channel pattern 131, forming a trench penetrating the barrier layer 136, and then filling the trench with an insulating material. The insulating material constituting the separation structure 160 may include the same material as the protective layer 140. For example, the insulating material constituting the separation structure 160 may include oxide such as SiO₂ or Al₂O₃. As another example, the insulating material constituting the separation structure 160 may include nitride such as SiN or oxynitride such as SiON. However, it is not limited thereto, the insulating material constituting the separation structure 160 may include a material different from the protective layer 140. At this time, at least part of the main channel layer 132 and/or the channel pattern 131 may be recessed together.

Hereinafter, the resistance unit of the semiconductor device according to some implementations will be described with further reference to FIG. 7 and FIG. 8.

FIG. 7 is a circuit diagram showing a resistance unit of a semiconductor device according to some implementations. FIG. 8 is a graph showing a resistance value according to a temperature change of a resistance unit of a semiconductor device according to some implementations.

As described above, the resistance unit 300 of the semiconductor device according to some implementations may be connected to the semiconductor unit 100 of the main element area TA and an external element. For example, the second contact electrode CT2 of the resistance unit 300 may be electrically connected to any one of the source electrode 173, the drain electrode 175, and the gate electrode 155 of the semiconductor unit 100, and the first contact electrode CT1 of the resistance unit 300 may be electrically connected to an external element, thereby receiving a signal with a predetermined voltage from the outside. However, it is not limited thereto, the relationship between the resistance unit 300 and the semiconductor unit 100 may be changed in various ways. Hereinafter, for better comprehension and ease of description, it is described that a first node N1 of the first contact electrode CT1 is connected to an external element, and a second node N2 of the second contact electrode CT2 is connected to the semiconductor unit 100. Here, the first node N1 may correspond to the first contact electrode CT1, and the second node N2 may correspond to the second contact electrode CT2.

Referring further to FIG. 7, the resistance unit 300 of the semiconductor device according to some implementations may include a resistance component having a predetermined resistance value. For example, the resistance unit 300 includes a first contact resistance RC1 in the first contact interface CF1 between the first contact electrode CT1 and the second drift area DTR2, a resistance RD of the second drift area DTR2, and a second contact resistance RC2 in the second contact interface CF2 between the second contact electrode CT2 and the second drift area DTR2. The first node N1 and the second node N2 may be connected through the first contact resistance RC1, the resistance RD of the second drift area DTR2, and the second contact resistance RC2 of the resistance unit 300. Here, a resistance R of the resistance unit 300 may mean a resistance between the first node N1 and the second node N2. The first node N1 may correspond to the first contact electrode CT1, and the second node N2 may correspond to the second contact electrode CT2, but it is not limited thereto.

In some implementations, the first contact resistance RC1, the resistance RD of the second drift area DTR2, and the second contact resistance RC2 may be coupled in series. That is, between the first node N1 and the second node N2, the first contact resistance RC1, the resistance RD of the second drift area DTR2, and the second contact resistance RC2 may be coupled in series. Accordingly, the resistance R of the resistance unit 300 may be defined as the sum of the first contact resistance RC1, the resistance RD of the second drift area DTR2, and the second contact resistance RC2. This may be due to the structural characteristic in which the second drift area DTR2 formed by the channel pattern 131 and the barrier layer 136 is positioned between the first contact electrode CT1 and the second contact electrode CT2.

Referring further to FIG. 8, the resistance R of the resistance unit 300 of the semiconductor device according to some implementations may have a constant value without the relationship to a temperature. That is, the sum of the first contact resistance RC1, the resistance RD of the second drift area DTR2, and the second contact resistance RC2 coupled in series between the first node N1 and the second node N2 may have a constant value without the relationship to a temperature. For example, the resistance R of the resistance unit 300 at the first temperature may be substantially the same as the resistance R of the resistance unit 300 at a second temperature that is different from the first temperature.

Meanwhile, the first contact resistance RC1, the resistance RD of the second drift area DTR2, and the second contact resistance RC2 may each have different resistance values depending on a temperature.

Referring specifically, the first contact resistance RC1 and the second contact resistance RC2 according to a temperature have the relationship of Equation 1 below.

$$RC = {A}_{1} T + {K}_{1} [ Ω / μm ] \qquad ( Equation 1 )$$

Here, RC means a resistance value (Ω) of the first contact resistance RC1 and the second contact resistance RC2, T means a temperature (° C.), and A1 is a temperature coefficient of resistance (TCR) of the first contact resistance RC1 and the second contact resistance RC2. Also, K1 is a constant. At this time, the temperature coefficient of resistance (TCR:) of the first contact resistance RC1 and the second contact resistance RC2 may have a negative value. For example, the temperature coefficient of resistance (TCR:) of the first contact resistance RC1 and the second contact resistance RC2 may be about −20 (Ω/° C.) to about −10 (Ω/° C.). Accordingly, the first contact resistance RC1 and the second contact resistance RC2 may become smaller as a temperature increases.

Next, the resistance RD of the second drift area DTR2 according to the temperature has the relationship of Equation 2 below.

$$RDU = {A}_{2} T + {K}_{2} [ Ω / μm ] \qquad ( Equation 2 )$$

Here, RDU means a unit resistance (Ω) of the second drift area DTR2 per a unit length (μm), T means a temperature (° C.), and A2 means a temperature coefficient of resistance (TCR) of the second drift area DTR2. Also, K2 is a constant. The unit resistance (RDU) of the second drift area DTR2 may mean the resistance value per a unit length of the resistance RD of the second drift area DTR2. At this time, the temperature coefficient of resistance of the second drift area DTR2 may have a positive value. For example, the temperature coefficient of resistance of the second drift area DTR2 may about 5 (Ω/μm° C.) to about 15 (Ω/μm° C.). Accordingly, the resistance RD of the second drift area DTR2 may increase as the temperature increases. In some implementations, the temperature coefficient of resistance of the second drift area DTR2 may be less than the temperature coefficient of resistance TCR of the first contact resistance RC1, but the disclosure is not limited thereto.

The resistance RD of the second drift area DTR2 may be calculated by multiplying the unit resistance RDU of the second drift area DTR2 by the length of the second drift area DTR2. For example, if the length LT of second drift area DTR2 along the first direction (the X direction) is 1 μm to 10 μm, the resistance RD of the second drift area DTR2 may be 1 times to 10 times the unit resistance RDU of the second drift area DTR2. In other words, the resistance of the second drift area DTR2 may be expressed by Equation 3 below.

$$RD = ( LT ) RDU = ( LT ) {A}_{2} T ( LT ) {K}_{2} [ Ω / um ] \qquad ( Equation 3 )$$

Here, RD may mean the resistance (Ω) of the second drift area DTR2, and LT may mean the length (μm) of the second drift area DTR2 along the first direction (the X direction).

In other words, the amount of the change in the resistance RD of the second drift area DTR2 with respect to the change in the temperature may depend on the temperature coefficient of resistance of the second drift area DTR2 and the length LT of the second drift area DTR2 along with the first direction (the X direction). Meanwhile, the amount of the change in the first contact resistance RC1 and the second contact resistance RC2 with respect to the change in the temperature may mostly depend on the temperature coefficient of resistance of the first contact resistance RC1 and the second contact resistance RC2.

In some implementations, even if the first contact resistance RC1 and the second contact resistance RC2 have the negative temperature coefficient of resistance, and the second drift area DTR2 has the positive temperature coefficient of resistance, when the length LT of the second drift area DTR2 along the first direction (the X direction) has a predetermined range, the resistance R of the resistance unit 300 may have a constant value without the relationship to a temperature. For example, when the length LT of second drift area DTR2 along the first direction (the X direction) is 1 μm to 10 μm, the temperature coefficient of resistance of the resistance R of the resistance unit 300 may be about 0 (Ω/° C.). The length LT of the second drift area DTR2 along the first direction (the X direction) may be 3 μm to 4 μm.

Accordingly, when an external signal with a predetermined voltage is applied to the semiconductor unit 100 through the resistance unit 300, even if the first contact resistance RC1 of the resistance unit 300, the resistance RD of the second drift area DTR2, and the second contact resistance RC2 in the semiconductor device according to some implementations have different resistances depending on temperature, the resistance R of the resistance unit 300 may have the constant value without the relationship to the temperature. Accordingly, even if the surrounding temperature of the semiconductor device according to some implementations changes, a voltage (or a current) within a predetermined range may be applied to the semiconductor unit 100, and the reliability of the semiconductor device may be improved.

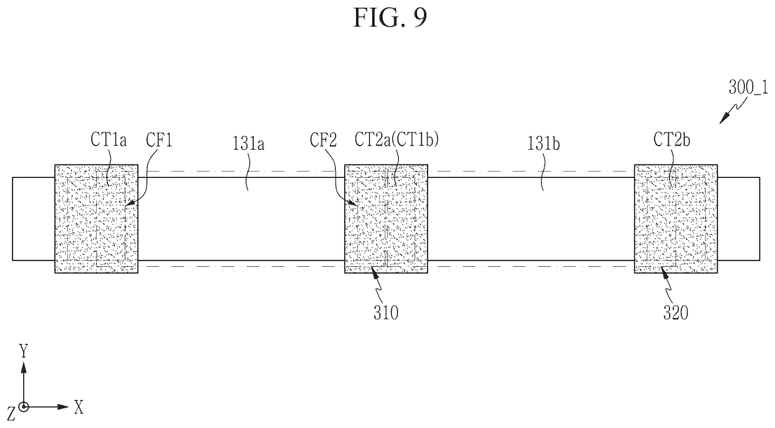

Hereinafter, the resistance unit of the semiconductor device according to some implementations is described with reference to FIG. 9 to FIG. 22.

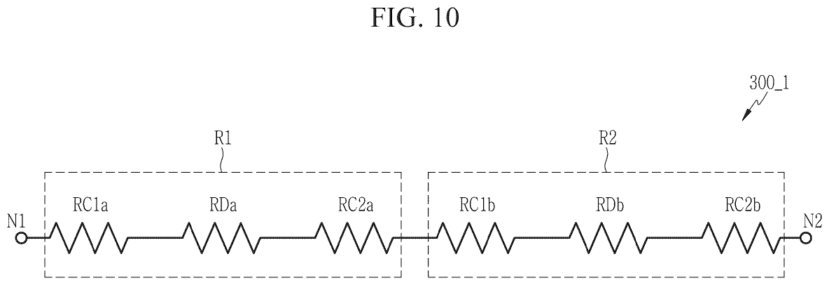

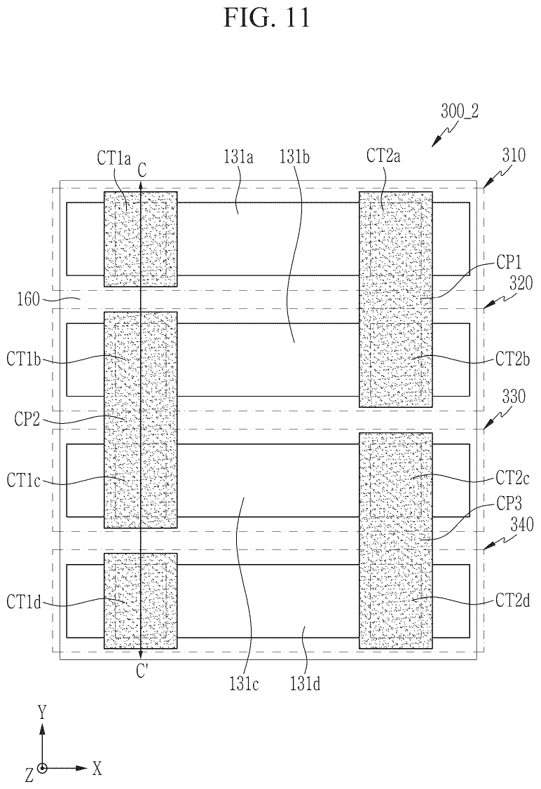

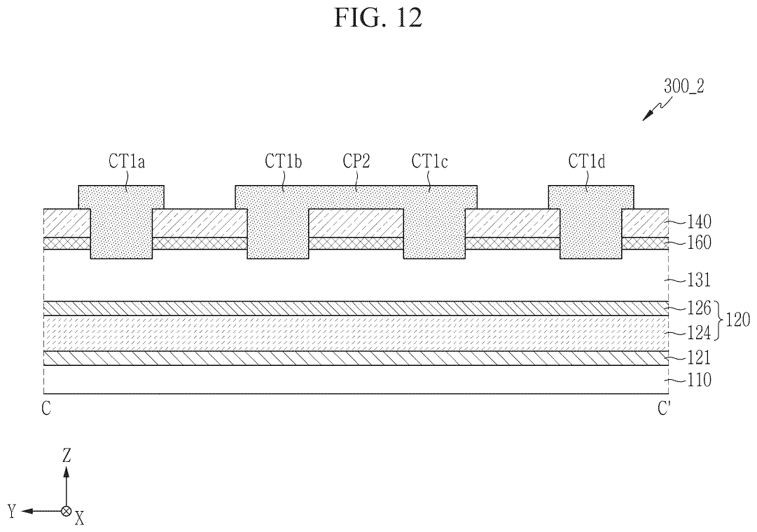

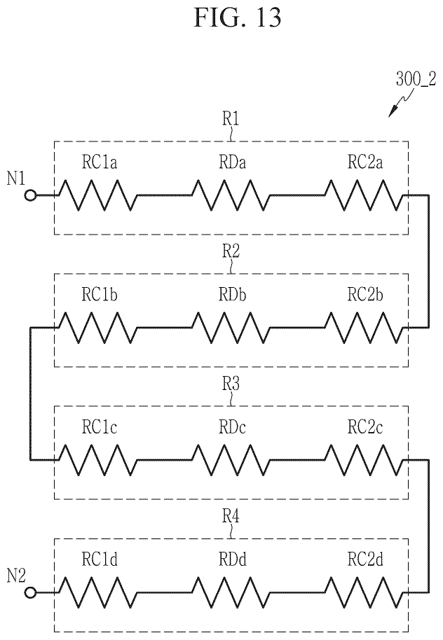

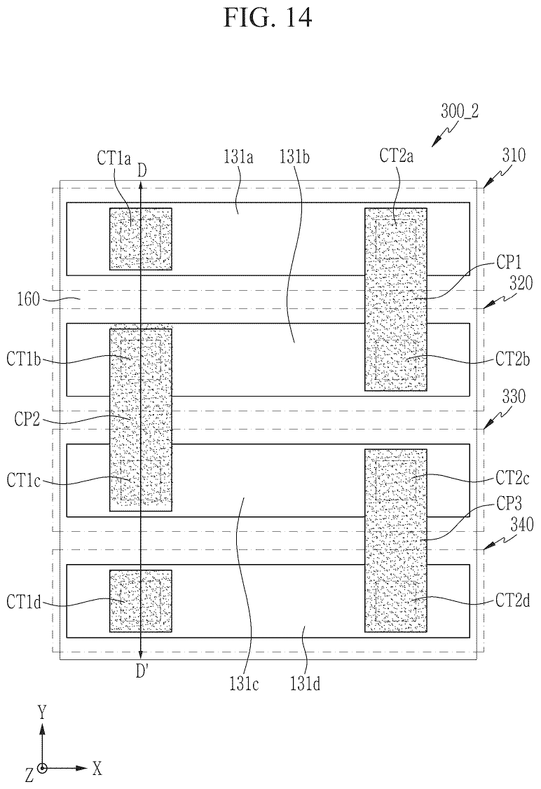

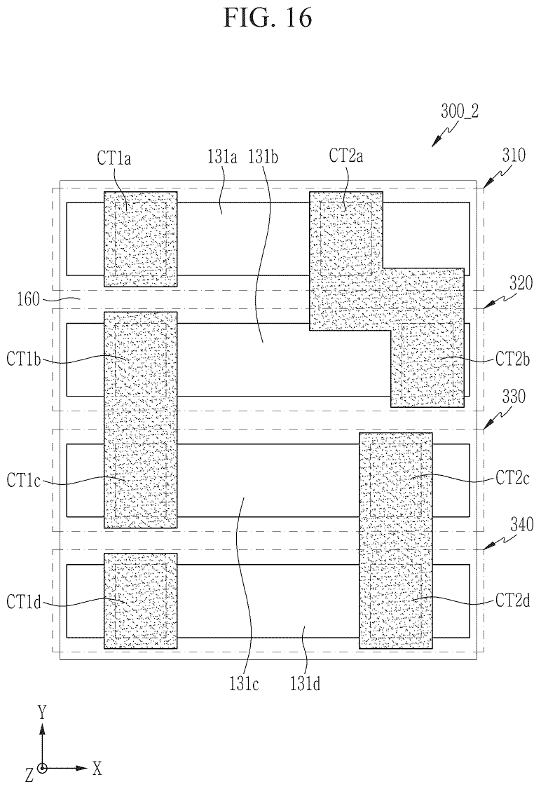

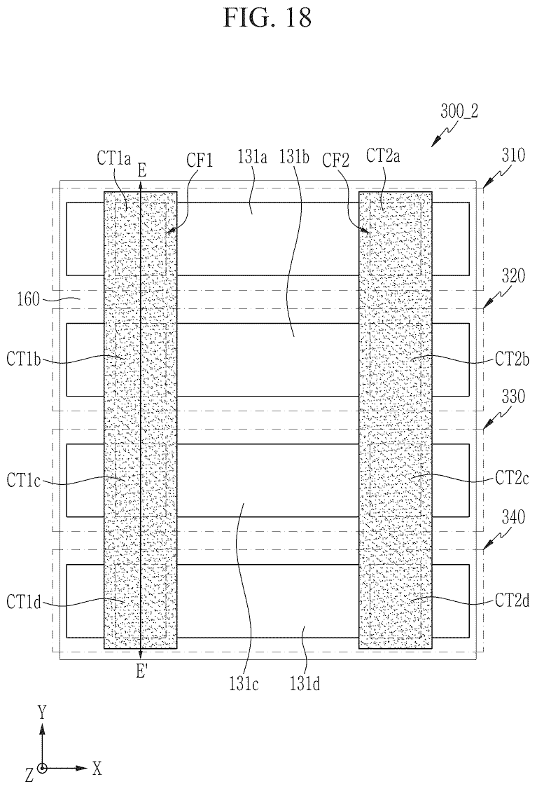

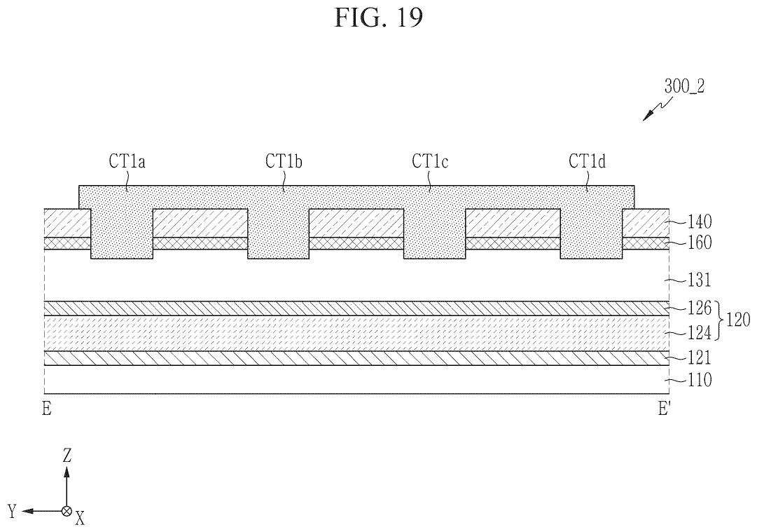

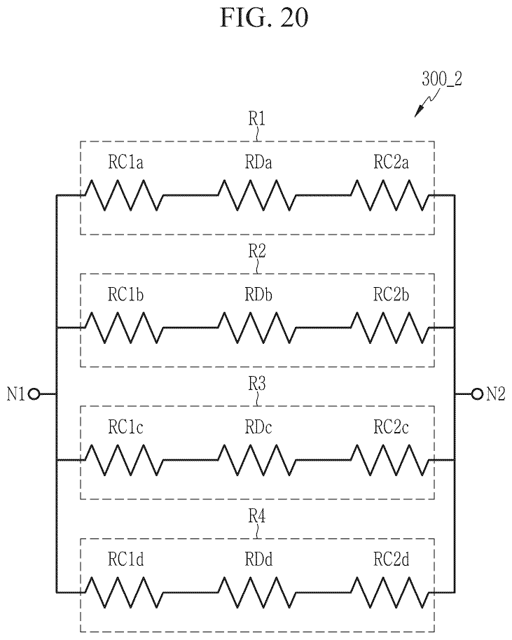

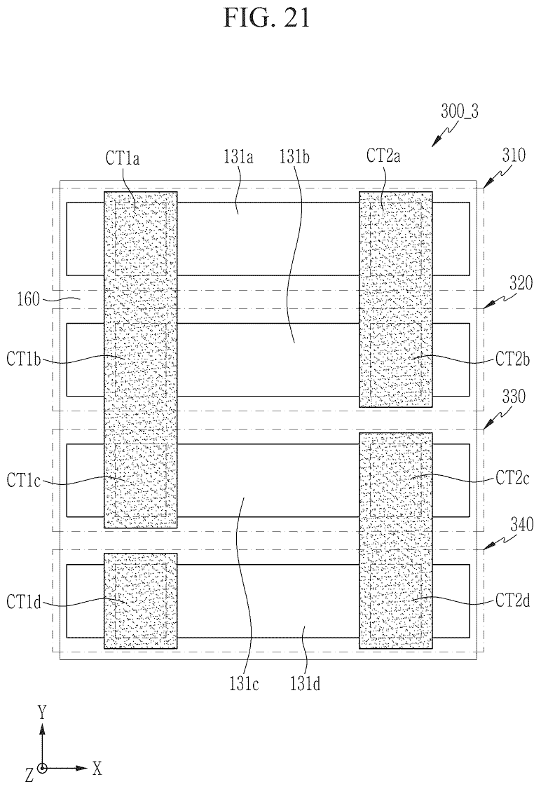

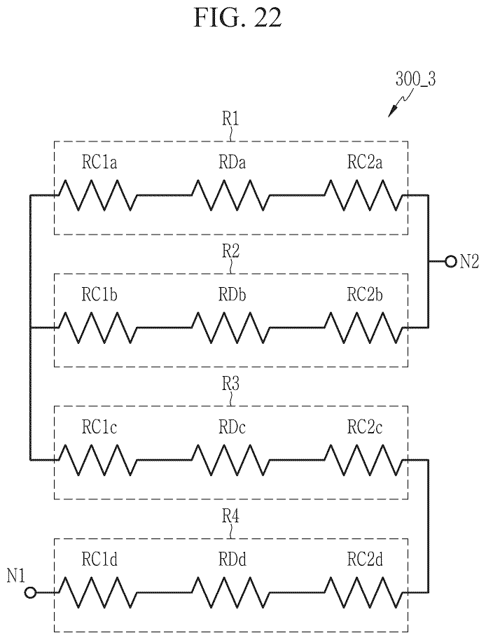

FIG. 9 is a top plan view showing a resistance unit of a semiconductor device according to some implementations. FIG. 10 is a circuit diagram showing a resistance unit of a semiconductor device in FIG. 9. FIG. 11 is a top plan view showing a resistance unit of a semiconductor device according to some implementations. FIG. 12 is a cross-sectional view cut along a line C-C′ in FIG. 11. FIG. 13 is a circuit diagram showing a resistance unit of a semiconductor device of FIG. 11. FIG. 14 is a top plan view showing a resistance unit of a semiconductor device according to some implementations. FIG. 15 is a cross-sectional view cut along a line D-D′ of FIG. 14. FIG. 16 to FIG. 18 are top plan views showing a resistance unit of a semiconductor device according to some implementations. FIG. 19 is a cross-sectional view cut along a line E-E′ of FIG. 18. FIG. 20 is a circuit diagram showing a resistance unit of a semiconductor device of FIG. 18. FIG. 21 is a top plan view showing a resistance unit of a semiconductor device according to some implementations. FIG. 22 is a circuit diagram showing a resistance unit of a semiconductor device of FIG. 21.

FIG. 9 to FIG. 22 show numerous variations of the semiconductor device according to some implementations shown in FIG. 1 to FIG. 8. The implementations shown in FIG. 9 to FIG. 22 include many parts that are the same as the implementations shown in FIG. 1 to FIG. 8 so that the description thereof is omitted and the differences will be mainly explained. Additionally, the same reference numerals are used for the same components as the previous implementations.

First, referring to FIG. 9 and FIG. 10, the semiconductor device according to some implementations may have a plurality of resistance units 300_1.

The plurality of resistance units 310 and 320 may be arranged along one direction. For example, as shown in FIG. 9, the plurality of resistance units 310 and 320 may extend in the same direction as the channel patterns 131a and 131b of the plurality of resistance units 310 and 320, respectively. That is, the first channel pattern 131a of the first resistance unit 310 and the second channel pattern 131b of the second resistance unit 320 may extend in the first direction (the X direction), and the first resistance unit 310 and the second resistance unit 320 may be arranged along the first direction (the X direction).

In some implementations, each of the first resistance unit 310 and the second resistance unit 320 may correspond to the resistance unit 300 of the implementations of FIG. 1 to FIG. 8. That is, the first channel pattern 131a of the first resistance unit 310 and the second channel pattern 131b of the second resistance unit 320 may have the same arrangement, shape, structure, and material as the channel pattern 131 of FIG. 1 to FIG. 8, and the contact electrodes CT1a and CT2a of the first resistance unit 310 and the contact electrodes CT1b and CT2b of the second resistance unit 320 may have the same arrangement, shape, structure, and material as the contact electrodes CT1 and CT2 of FIG. 1 to FIG. 8.

In some implementations, the length that the first channel pattern 131a of the first resistance unit 310 and the second channel pattern 131b of the second resistance unit 320 extend in the first direction (the X direction) may be substantially the same. For example, the length between the first contact interface of the first channel pattern 131a in contact with the first contact electrode CT1a of the first resistance unit 310 and the second contact interface of the first channel pattern 131a in contact with the second contact electrode CT2a of the first resistance unit 310 may be substantially the same as the length between the first contact interface of the second channel pattern 131b in contact with the first contact electrode CT1b of the second resistance unit 320 and the second contact interface of the second channel pattern 131b in contact with the second contact electrode CT2b of the second resistance unit 320. In other words, the length of the first channel pattern 131a along the first direction (the X direction) between the first contact electrode CT1a and the second contact electrode CT2a of the first resistance unit 310 may be substantially the same as the length of the second channel pattern 131b along the first direction (the X direction) between the first contact electrode CT1b and the second contact electrode CT2b of the second resistance unit 320.

In some implementations, the plurality of resistance units 310 and 320 may be electrically connected. At this time, the plurality of resistance units 310 and 320 may be coupled in series. As an example, the first contact electrode CT1a of the first resistance unit 310 may be connected to an external element, the second contact electrode CT2a of the first resistance unit 310 and the first contact electrode CT1b of the second resistance unit 320 may be connected, and the second contact electrode CT2b of the second resistance unit 320 may be connected to one of the source electrode 173, the drain electrode 175, and the gate electrode 155 of the semiconductor unit 100, but the disclosure is not limited thereto.

At this time, the second contact electrode CT2a of the first resistance unit 310 and the first contact electrode CT1b of the second resistance unit 320 may be integrated. In other words, the second contact electrode CT2a of the first resistance unit 310 and the first contact electrode CT1b of the second resistance unit 320 may be integrally formed by the same process. However, it is not limited thereto, the second contact electrode CT2a of the first resistance unit 310 and the first contact electrode CT1b of the second resistance unit 320 may be configured separately and may be connected through a separate wire.

Referring to FIG. 10, as the plurality of resistance units 310 and 320 are coupled in series, the resistance of the resistance unit 300_1 of the semiconductor device according to some implementations may be the sum of the resistance R1 of the first resistance unit 310 and the resistance R2 of the second resistance unit 320. Here, the resistance R1 of the first resistance unit 310 includes a first contact resistance RC1a between the first contact electrode CT1a of the first resistance unit 310 and the first channel pattern 131a, a resistance RDa of the second drift area formed within the first channel pattern 131a, and a second contact resistance RC2a between the second contact electrode CT2a of the first resistance unit 310 and the first channel pattern 131a. In addition, the resistance R2 of the second resistance unit 320 includes a first contact resistance RC1b between the first contact electrode CT1b of the second resistance unit 320 and the second channel pattern 131b, a resistance RDb of the second drift area formed within the second channel pattern 131b, and a second contact resistance RC2b between the second contact electrode CT2b of the second resistance unit 320 and the second channel pattern 131b.

In some implementations, the first resistance unit 310 and the second resistance unit 320 may have constant resistance values regardless of a temperature. The explanation thereof is substantially the same as the description of the resistance element 300 in the implementations of FIG. 1 to FIG. 8 so that it is omitted. Accordingly, since the first resistance unit 310 and the second resistance unit 320 each have the constant resistance value regardless of temperature, even when connecting the plurality of resistance units 310 and 320, the resistance unit 300_1 of the semiconductor device according to some implementations may have a constant resistance value regardless of a temperature. Therefore, by connecting the plurality of resistance units 310 and 320 in various ways, it is possible to easily design the element with a constant resistance value regardless of a temperature.

Referring to FIG. 11 to FIG. 22, the semiconductor device according to some implementations may have a plurality of resistance units 300, and the plurality of resistance units 310 to 340 may be arranged along one direction.

In the implementations of FIG. 11 to FIG. 22, the arrangement direction of the plurality of resistance units 310 to 340 may be different from the elongation direction of each channel pattern 131a to 131d of the plurality of resistance units 310 to 340. That is, the first channel pattern 131a of the first resistance unit 310, the second channel pattern 131b of the second resistance unit 320, the third channel pattern 131c of the third resistance unit 330, and the fourth channel pattern 131d of the fourth resistance unit 340 may extend in the first direction (the X direction), and the first resistance unit 310 to the fourth resistance unit 340 may be arranged along the second direction (the Y direction).

In some implementations, the first resistance unit 310 to the fourth resistance unit 340, respectively, may correspond to the resistance unit 300 of the implementations of FIG. 1 to FIG. 8. That is, the first channel pattern 131a of the first resistance unit 310, the second channel pattern 131b of the second resistance unit 320, the third channel pattern 131c of the third resistance unit 330, and the fourth channel pattern 131d of the fourth resistance unit 340 may have the same arrangement, shape, structure, and material as the channel pattern 131 of FIG. 1 to FIG. 8, and the contact electrodes CT1a and CT2a of the first resistance unit 310, the contact electrodes CT1b and CT2b of the second resistance unit 320, the contact electrodes CT1c and CT2c of the third resistance unit 330, and the contact electrodes CT1d and CT2d of the fourth resistance unit 340 may have the same arrangement, shape, structure, and material as the contact electrodes CT1 and CT2 of FIG. 1 to FIG. 8.

In some implementations, the lengths that the channel patterns 131a to 131d of each of the plurality of resistance units 310 to 340 extends in the first direction (the X direction) may be substantially the same. For example, the length between the first contact interface of the first channel pattern 131a in contact with the first contact electrode CT1a of the first resistance unit 310 and the second contact interface of the first channel pattern 131a in contact with the second contact electrode CT2a of the first resistance unit 310 may be substantially the same as the length between the first contact interface of the second channel pattern 131b in contact with the first contact electrode CT1b of the second resistance unit 320 and the second contact interface of the second channel pattern 131b in contact with the second contact electrode CT2b of the second resistance unit 320. In other words, the length of the first channel pattern 131a along the first direction (the X direction) between the first contact electrode CT1a and the second contact electrode CT2a of the first resistance unit 310 may be substantially the same as the length of the second channel pattern 131b along the first direction (the X direction) between the first contact electrode CT1b and the second contact electrode CT2b of the second resistance unit 320. This may be similarly applied to the third resistance unit 330 and the fourth resistance unit 340.

In some implementations, the plurality of resistance units 310 to 340 may be separated by a separation structure 160. For example, the separation structure 160 may be positioned parallel to the channel pattern 131 so that the plurality of channel patterns 131a to 131d may be separated by the separation structure 160. In some implementations, the separation structure 160 may recess at least a portion of the channel pattern 131, but it is not limited thereto. For example, the separation structure 160 may completely penetrate the channel pattern 131 and be in contact with the protective layer 140. As another example, the separation structure 160 may not penetrate the channel pattern 131. In other words, the lower surface of the separation structure 160 may be positioned at substantially the same level as the lower surface of the barrier layer 136. The separation structure 160 may be formed by forming a barrier layer 136 on the main channel layer 132 and the channel pattern 131 and performing an ion implant process within the barrier layer 136 positioned between the plurality of resistance units 310-340.

In some implementations, the separation structure 160 may be formed by forming a barrier layer 136 on the main channel layer 132 and the channel pattern 131 and performing an ion implant process within the barrier layer 136 positioned between the semiconductor unit 100 and the resistance unit 300. However, it is not limited thereto, the separation structure 160 may be formed by forming a barrier layer 136 on the main channel layer 132 and the channel pattern 131, forming a trench penetrating the barrier layer 136, and then filling the trench with an insulating material. The insulating material constituting the separation structure 160 may include the same material as the protective layer 140. For example, the insulating material constituting the separation structure 160 may include oxide such as SiO₂ or Al₂O₃. As another example, the insulating material constituting the separation structure 160 may include nitride such as SiN or oxynitride such as SiON. However, it is not limited thereto, the insulating material constituting the separation structure 160 may include a material different from the protective layer 140. At this time, at least part of the main channel layer 132 and/or the channel pattern 131 may be recessed together.

In some implementations, the plurality of resistance units 310 to 340 may be electrically connected to each other.

For example, as shown in FIG. 11 to FIG. 13, the plurality of resistance units 310 to 340 may be coupled in series. As an example, the first contact electrode CT1a of the first resistance unit 310 may be electrically connected to an external element as a first node N1, the second contact electrode CT2a of the first resistance unit 310 and the second contact electrode CT2b of the second resistance unit 320 may be electrically connected, the first contact electrode CT1b of the second resistance unit 320 and the first contact electrode CT1c of the third resistance unit 330 may be electrically connected, the second contact electrode CT2c of the third resistance unit 330 and the second contact electrode CT2d of the fourth resistance unit 340 may be electrically connected, and the first contact electrode CT1d of the fourth resistance unit 340 may be electrically connected to any one of the source electrode 173, the drain electrode 175, and the gate electrode 155 of the semiconductor unit 100as as a second node N2 and, but it is not limited thereto. Additionally, in some implementations, the plurality of resistance units 310 to 340 may have a resistance component. For example, as shown in FIG. 13, the resistance components of the first to fourth resistance units 310 to 340 may each correspond to the first to fourth resistances R1 to R4 in FIG. 13. In some implementations, the first contact electrode CT1a of the first resistance unit 310 is described as corresponding to the first node N1, but the disclosure is not limited thereto. For example, the first contact electrode CT1a of the first resistance unit 310 may be electrically connected to a separate electrode corresponding to the first node N1.

In some implementations, the second contact electrode CT2a of the first resistance unit 310 and the second contact electrode CT2b of the second resistance unit 320 may be integrated. That is, the second contact electrode CT2a of the first resistance unit 310 and the second contact electrode CT2b of the second resistance unit 320 may be integrally formed in the same process. At this time, a first connection CP1 connecting the second contact electrode CT2a of the first resistance unit 310 and the second contact electrode CT2b of the second resistance unit 320 may overlap the separation structure 160 and the protective layer 140 in the third direction (the Y direction). The first connection CP1 may cover the upper surface of the protective layer 140.

This may be also applied similarly between the first contact electrode CT1b of the second resistance unit 320 and the first contact electrode CT1c of the third resistance unit 330, and between the second contact electrode CT2c of the third resistance unit 330 and the second contact electrode CT2d of the fourth resistance unit 340. That is, the first contact electrode CT1b of the second resistance unit 320 and the first contact electrode CT1c of the third resistance unit 330 may be integrated. Additionally, the second contact electrode CT2c of the third resistance unit 330 and the second contact electrode CT2d of the fourth resistance unit 340 may be integrated. At this time, a second connection CP2 connecting the first contact electrode CT1b of the second resistance unit 320 and the first contact electrode CT1c of the third resistance unit 330 and a third connection CP3 connecting the second contact electrode CT2c of the third resistance unit 330 and the second contact electrode CT2d of the fourth resistance unit 340 may overlap the separation structure 160 and the protective layer 140 in the third direction (the Y direction).

Hereinafter, the plurality of integrally formed contact electrodes is referred to as a contact group. That is, in some implementations, the second contact electrode CT2a of the first resistance unit 310, the second contact electrode CT2b of the second resistance unit 320, and the first connection CP1 may be referred to as a first contact group, the first contact electrode CT1b of the second resistance unit 320, the first contact electrode CT1c of the third resistance unit 330, and the second connection CP2 may be referred to as a second contact group, and the second contact electrode CT2c of the third resistance unit 330, the second contact electrode CT2d of the fourth resistance unit 340, and the third connection CP3 may be referred to as a third contact group. In some implementations, a plurality of contact groups may be alternately positioned on one side and the other side of the channel pattern 131 on a plane. For example, on a plane including the first direction (the X direction) and the second direction (the Y direction), the first contact group may be positioned on one side of the first channel pattern 131a and one side of the second channel pattern 131b, and the second contact group may be positioned on the other side of the second channel pattern 131b and the other side of the third channel pattern 131c. Additionally, the third contact group may be positioned on one side of the third channel pattern 131c and on one side of the fourth channel pattern 131d, but it is not limited thereto. Accordingly, the first to fourth resistance units 310 to 340 may be coupled in series.

In some implementations, the width of each of the plurality of contact electrodes CT1a to CT1d and CT2a to CT2d may be greater than the width of the channel patterns 131a to 131d. For example, as shown in FIG. 11 and FIG. 12, the maximum width of each of the plurality of contact electrodes CT1a to CT1d and CT2a to CT2d along the second direction (the Y direction) may be larger than the width of the channel patterns 131a to 131d along the second direction (the Y direction). Specifically, the width of the plurality of contact electrodes CT1a to CT1d and CT2a to CT2d positioned within the space where at least a portion of the channel patterns 131a to 131d is recessed along the second direction (the Y direction) may be substantially the same as the width of the channel patterns 131a to 131d along the second direction (the Y direction), and the width of the plurality of contact electrodes CT1a to CT1d and CT2a to CT2d protruded from the upper surface of the channel patterns 131a to 131d along the second direction (the Y direction) may be larger than the width of the channel patterns 131a to 131d along in the second direction (the Y direction).

However, it is not limited thereto, as another example, as shown in FIG. 14 and FIG. 15, the maximum width of each of the plurality of contact electrodes CT1a to CT1d and CT2a to CT2d along the second direction (the Y direction) may be substantially smaller than or the same as the width of the channel patterns 131a to 131d along the second direction (the Y direction). In this case, the barrier layer 136 may be further positioned between the plurality of contact electrodes CT1a to CT1d and CT2a to CT2d adjacent in the second direction (the Y direction). That is, the separation structure 160 may be positioned between the plurality of contact electrodes CT1a to CT1d and CT2a to CT2d adjacent in the second direction (the Y direction), and the barrier layer 136 may be positioned between the plurality of contact electrodes CT1a to CT1d and CT2a to CT2d and the separation structure 160. For example, as shown in FIG. 15, the barrier layer 136 may be further positioned between the first contact electrode CT1a of the first resistance element 310 and the separation structure 160 and between the first contact electrode CT1b of the second resistance element 320 and the separation structure 160. Accordingly, the separation structure 160 may be positioned spaced apart from the first contact electrode CT1a of the first resistance element 310 and the first contact electrode CT1b of the second resistance element 320 in the second direction (the Y direction). Additionally, at least some of the plurality of contact electrodes CT1a to CT1d and CT2a to CT2d may overlap the barrier layer 136 in the third direction (the Y direction), but it is not limited thereto.

In FIG. 11, FIG. 12, FIG. 14, and FIG. 15, at least some of the plurality of contact electrodes CT1a to CT1d and CT2a to CT2d are shown as being integrated through the connection parts CP1 to CP3, but it is not limited thereto. For example, the plurality of contact electrodes CT1a to CT1d and CT2a to CT2d may be formed first, and then the connection portion may be formed separately. As another example, after forming a plurality of contact electrodes CT1a to CT1d and CT2a to CT2d and forming an insulating layer that covers the plurality of contact electrodes CT1a to CT1d and CT2a to CT2d, electrodes that penetrate the insulating layer may be formed. In this case, at least some of the plurality of contact electrodes CT1a to CT1d and CT2a to CT2d may be electrically connected through the electrodes that penetrate the insulating layer and are electrically connected to the plurality of contact electrodes CT1a to CT1d and CT2a to CT2d. In some implementations, each of the first resistance unit 310 to the fourth resistance unit 340 may have a constant resistance value regardless of temperature. The explanation of this is substantially the same as the description of the resistance element 300 in the implementations of FIG. 1 to FIG. 88, so it is omitted. Accordingly, since each of the first resistance units 310 to fourth resistance units 340 has a constant resistance value regardless of a temperature, even when the plurality of resistance units 310 to 340 are series or coupled in parallel, the resistance unit 300_2 of the semiconductor devices according to some implementations may have a constant resistance value regardless of a temperature. Therefore, without having to consider changes in the resistance value depending on the temperature, the plurality of resistance units 310 to 340 may be connected in various ways to easily design an element with a constant resistance value regardless of a temperature.

However, it is not limited thereto, at least some of the plurality of resistance units 310 to 340 may have a positive temperature coefficient of resistance (TCR), and others may have a negative temperature coefficient of resistance (TCR). However, even in this case, the resistance of the plurality of resistance units 310 to 340 may have a constant resistance value regardless of a temperature. For example, as shown in FIG. 16, the first resistance unit 310 may have a negative temperature coefficient of resistance (TCR), and the second resistance unit 320 may have a positive temperature coefficient of resistance (TCR). At this time, the third resistance unit 330 and the fourth resistance unit 340 may have a constant resistance value regardless of a temperature. Specifically, the extension length of the first channel pattern 131a of the first resistance unit 310 along the first direction (the X direction) may be shorter than the extension length of the third channel pattern 131c of the third resistance unit 330 along the first direction (the X direction). Accordingly, the resistance of the first resistance unit 310 may be less affected by the resistance component due to the drift area of the first channel pattern 131a, and the resistance of the first resistance unit 310 may have a negative temperature coefficient of resistance (TCR). Additionally, the extension length of the second channel pattern 131b of the second resistance unit 320 along the first direction (the X direction) may be longer than the extension length of the third channel pattern 131c of the third resistance unit 330 along the first direction (the X direction). Accordingly, the resistance of the third resistance unit 330 may be more affected by the resistance component due to the drift area of the third channel pattern 131c, and the resistance of the third resistance unit 330 may have a positive temperature coefficient of resistance (TCR). However, even in this case, the sum of the resistance of the first resistance unit 310 and the resistance of the second resistance unit 320 may have a constant value regardless of a temperature.

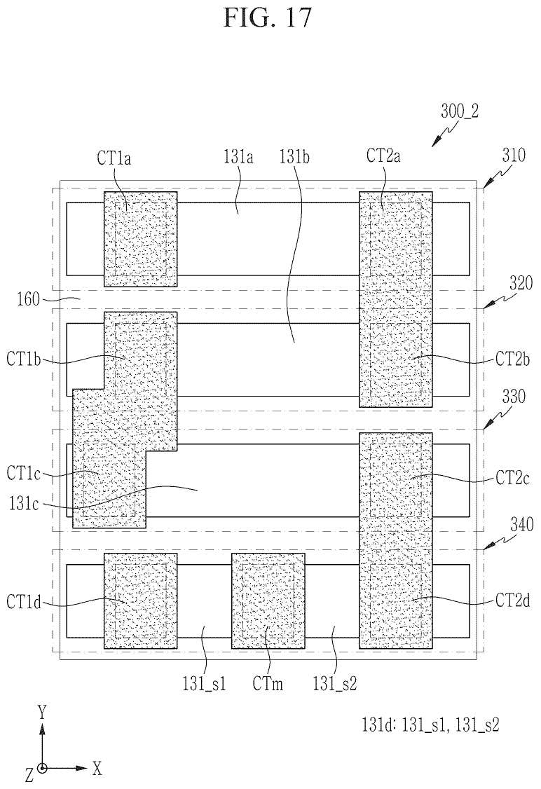

As another example, as shown in FIG. 17, in some implementations, the fourth resistance unit 340 may further include a middle contact electrode CTm between the first contact electrode CT1d and the second contact electrode CT2d. In this case, the fourth channel pattern 131d of the fourth resistance unit 340 may be separated into a first subchannel pattern 131_S1 between the first contact electrode CT1d of the fourth resistance unit 340 and the middle contact electrode CTm and a second subchannel pattern 131_S2 between the middle contact electrode CTm of the fourth resistance unit 340. CT2d and the second contact electrode CT2d. At this time, the extension length of the first subchannel pattern 131_S1 along the first direction (the X direction) may be shorter than the extension length of the second channel pattern 131b of the second resistance unit 320 along the first direction (the X direction). Additionally, the extension length of the second subchannel pattern 131_S2 along the first direction (the X direction) may be shorter than the extension length of the second channel pattern 131b of the second resistance unit 320 along the first direction (the X direction). Accordingly, the resistance of the fourth resistance unit 340 may have a negative temperature coefficient of resistance (TCR).

However, even in this case, the extension length of the third channel pattern 131c of the third resistance unit 330 along the first direction (the X direction) may be longer than the extension length of the second channel pattern 131b of the second resistance unit 320 along the first direction (X direction). Accordingly, the resistance of the third resistance unit 330 may be more affected on the resistance component due to the drift area of the third channel pattern 131c, and the third resistance unit 330 may have a positive temperature coefficient of resistance (TCR). Accordingly, the total sum of the resistances of the first resistance unit 310 to the fourth resistance unit 340 of the semiconductor device according to some implementations may have a constant value regardless of a temperature.

FIG. 16 and FIG. 17 shows that one resistance element has a positive temperature coefficient of resistance (TCR), but the number of the resistance elements with a positive temperature coefficient of resistance (TCR), and the number of the resistance elements with a negative temperature coefficient of resistance (TCR) are not limited thereto. For example, two or more resistance elements may have a positive temperature coefficient of resistance (TCR), or two or more resistance elements may have a negative temperature coefficient of resistance (TCR).

Also, as another example, as shown in FIG. 18 to FIG. 20, the plurality of resistance units 310 to 340 may be coupled in parallel. The first contact electrode CT1a of the first resistance unit 310, the first contact electrode CT1b of the second resistance unit 320, the first contact electrode CT1c of the third resistance unit 330, and the first contact electrode CT1d of the fourth resistance unit 340 may be electrically connected to the external element as a first node N1, and the second contact electrode CT2a of the first resistance unit 310, the second contact electrode CT2b of the second resistance unit 320, the second contact electrode CT2c of the third resistance unit 330, and the second contact electrode CT2d of the fourth resistance unit 340 may be electrically connected to any one of the source electrode 173, drain electrode 175, and gate electrode 155 of the semiconductor unit 100 as a second node N2. Additionally, in some implementations, the plurality of resistance units 310 to 340 may have a resistance component. For example, as shown in FIG. 20, the resistance components of the first to fourth resistance units 310 to 340 may each correspond to first to fourth resistances R1 to R4 in FIG. 20.

In some implementations, the first contact electrode CT1a of the first resistance unit 310, the first contact electrode CT1b of the second resistance unit 320, the first contact electrode CT1c of the third resistance unit 330, and the first contact electrode CT1d of the fourth resistance unit 340 may be integrally formed. That is, the first contact electrode CT1a of the first resistance unit 310, the first contact electrode CT1b of the second resistance unit 320, the first contact electrode CT1c of the third resistance unit 330, and the first contact electrode CT1d of the fourth resistance unit 340 may be integrally formed in the same process. At this time, connections may be established between the first contact electrode CT1a of the first resistance unit 310 and the first contact electrode CT1b of the second resistance unit 320, between the first contact electrode CT1b of the second resistance unit 320 and the first contact electrode CT1c of the third resistance unit 330, and between the first contact electrode CT1c of the third resistance unit 330 and the first contact electrode CT1d of the fourth resistance unit 340. The connection may overlap the separation structure 160 and the protective layer 140 in the third direction (the Y direction). The connection part may cover the upper surface of the protective layer 140.

In addition, the second contact electrode CT2a of the first resistance unit 310, the second contact electrode CT2b of the second resistance unit 320, the second contact electrode CT2c of the third resistance unit 330, and the second contact electrode CT2d of the fourth resistance unit 340 may be integrated. That is, the second contact electrode CT2a of the first resistance unit 310, the second contact electrode CT2b of the second resistance unit 320, the second contact electrode CT2c of the third resistance unit 330, and the second contact electrode CT2d of the fourth resistance unit 340 may be integrally formed in the same process. In this case, connections may be established between the second contact electrode CT2a of the first resistance unit 310 and the second contact electrode CT2b of the second resistance unit 320, between the second contact electrode CT2b of the second resistance unit 320 and the second contact electrode CT2c of the third resistance unit 330, and between the second contact electrode CT2c of the third resistance unit 330 and the second contact electrode CT2d of the fourth resistance unit 340. The connection may overlap the separation structure 160 and the protective layer 140 in the third direction (the Y direction). The connection may cover the upper surface of the protective layer 140.

FIG. 18 and FIG. 19 show that at least some of the plurality of contact electrodes CT1a to CT1d and CT2a to CT2d are integrally formed through the connection, but the disclosure is not limited thereto. For example, the plurality of contact electrodes CT1a to CT1d and CT2a to CT2d may be formed first and then the connection may be formed separately. As another example, after forming a plurality of contact electrodes CT1a to CT1d and CT2a to CT2d and forming an insulating layer that covers the plurality of contact electrodes CT1a to CT1d and CT2a to CT2d, electrodes that penetrate the insulating layer may be formed.

In some implementations, the first resistance unit 310 to the fourth resistance unit 340 may have a constant resistance value regardless of a temperature. The description thereof is substantially the same as the description of the resistance element 300 according to the implementations of FIG. 1 to FIG. 8. Accordingly, since each of the first resistance units 310 to fourth resistance units 340 has a constant resistance value regardless of a temperature, even when the plurality of resistance units 310 to 340 are series or coupled in parallel, the resistance unit 300_2 of the semiconductor device according to some implementations may have a constant resistance value regardless of a temperature. Therefore, it is possible to easily design an element with a constant resistance value regardless of a temperature by connecting the plurality of resistance units 310 to 340 in various ways.

In some implementations, four resistance units are shown in series or coupled in parallel, but this is not limited the and various combinations and changes are possible. For example, at least some of the plurality of resistance units 310 to 340 may be coupled in series, and the remaining portions may be coupled in parallel. For example, as shown in FIG. 21 and FIG. 22, the first resistance unit 310 and the second resistance unit 320 may be coupled in parallel, and the third resistance unit 330 and the fourth resistance unit 340 may be coupled in series with the first resistance unit 310. As an example, the second contact electrode CT2a of the first resistance unit 310 and the second contact electrode CT2b of the second resistance unit 320 may electrically connected to any one of the source electrode 173, the drain electrode 175, and the gate electrode 155 of the semiconductor unit 100 as a second node N2, the first contact electrode CT1a of the first resistance unit 310 and the first contact electrode CT1b of the second resistance unit 320 may be electrically connected to the first contact electrode CT1c of the third resistance unit 330, the second contact electrode CT2c of the third resistance unit 330 and the second contact electrode CT2d of the fourth resistance unit 340 may electrically connected, and the first contact electrode CT1d of the fourth resistance unit 340 may be electrically connected to an external element as a first node N1. Additionally, in some implementations, the plurality of resistance units 310-340 may have a resistance component. For example, as shown in FIG. 22, the resistance components of the first to fourth resistance units 310 to 340 may each correspond to the first to fourth resistances (R1 to R4 in FIG. 22). The relationship of the plurality of resistance units 310 to 340 disclosed in the implementations FIG. 21 and FIG. 22 is merely illustrative, and the number of plurality of resistance units 310-340 and the connection relationships thereof are but not limited thereto. The number of the plurality of resistance units 310 to 340 and the connection relationships thereof may be changed in various ways.

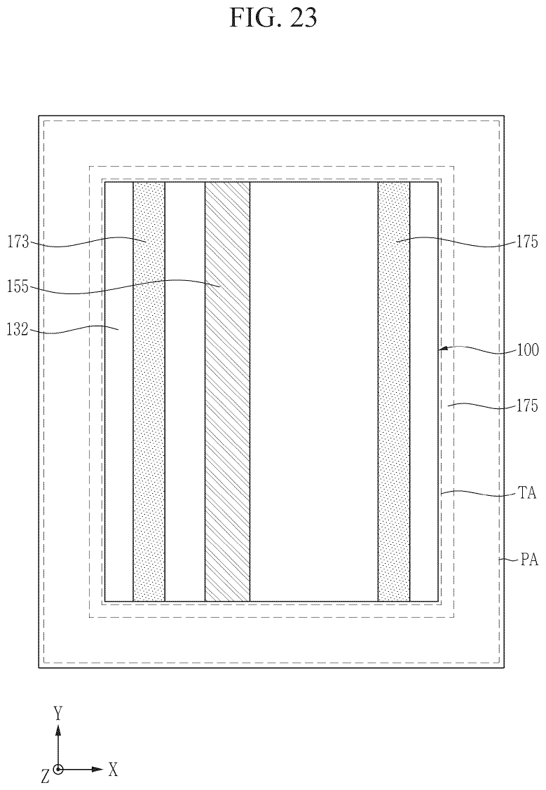

Hereinafter, the semiconductor device according to some implementations will be described with reference to FIG. 23.

FIG. 23 is a top plan view showing a semiconductor device according to some implementations. In the implementations of FIG. 23, for better understanding and ease of description, a semiconductor unit 100 positioned in the main element area TA, the peripheral circuit area PA, and the main element area TA is shown, and a resistance unit positioned in the peripheral circuit area PA is not shown. Although not shown in the drawing, it goes without saying that the resistance unit according to some implementations may be positioned within the peripheral circuit area PA.

Referring to FIG. 23, the peripheral circuit area PA may be positioned at least on one side of the main element area TA. For example, the peripheral circuit area PA may surround the side of the main element area TA. The peripheral circuit area PA may be positioned on one side and the other side of the main element area TA along the first direction (the X direction) and on one side and the other side of the main element area TA along the second direction (the Y direction), but the disclosure is not limited thereto. Accordingly, the resistance unit 300 may be positioned at least on one side of the semiconductor unit 100. In some implementations, a separation structure 160 may be positioned between the peripheral circuit area PA and the main element area TA, but the disclosure is not limited thereto.

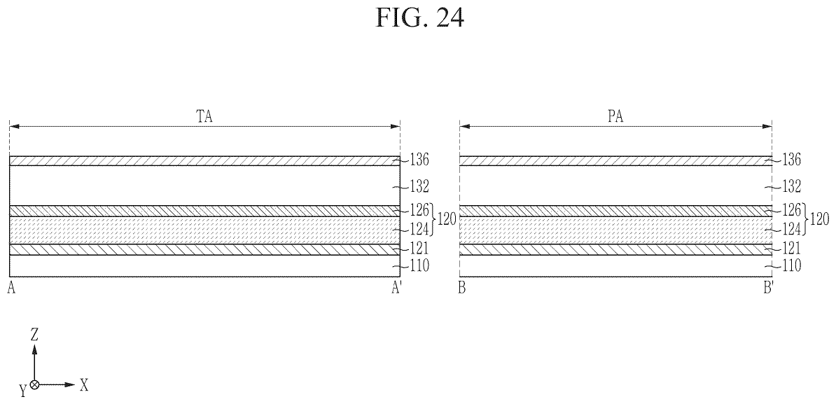

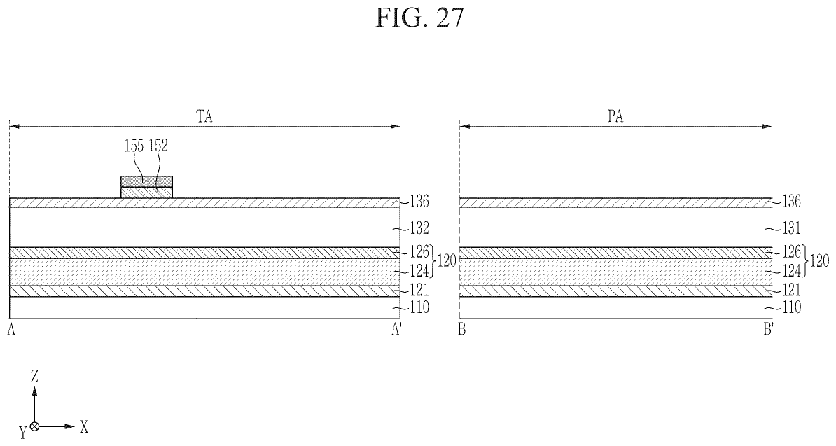

Hereinafter, a method of manufacturing a semiconductor device some implementations is described with reference to FIG. 24 to FIG. 30.

FIG. 24 to FIG. 30 are process cross-sectional views showing a method of manufacturing a semiconductor device in process order according to some implementations. FIG. 24 to FIG. 30 are the cross-sectional views corresponding to the area A-A′ in FIG. 1 and the area B-B′ of FIG. 4. FIG. 24 to FIG. 30 show the main element area TA and the peripheral circuit area PA.

As shown in FIG. 24, first, a seed layer 121 and a protective layer 140 may be formed sequentially on a substrate 110 in a main element area TA and a peripheral circuit area PA. In some embodiments, the protective layer 140 includes a superlattice layer 124 and a high resistance layer 126.

The substrate 110 may include a semiconductor material. For example, the substrate 110 may include sapphire, Si, SiC, AlN, GaN, or a combination thereof.

The substrate 110 may be a SOI (Silicon on Insulator) substrate. However, the material of the substrate 110 is not limited to this, and any generally-used substrate can be applied.

The seed layer 121 and the superlattice layer 124 may be formed sequentially using an epitaxial growth method. The seed layer 121 and the superlattice layer 124 may be made of the same-based semiconductor material. However, the material composition ratio of each layer may be different considering the role of each layer and the performance required for the semiconductor device. The seed layer 121 and the superlattice layer 124 may include one or more material selected from Group III-V materials, such as nitrides including Al, Ga, In, B, or a combination thereof. The seed layer 121 and the superlattice layer 124 may be AlₓIn_{y}Ga_{(1-x-y)}N (0≤x≤1, 0≤y≤1, x+y≤1). For example, the seed layer 121 and the superlattice layer 124 may include AlN, GaN, InN, InGaN, AlGaN, AlInN, AlInGaN, or a combination thereof.

In some embodiments, the superlattice layer 124 may be comprised of multiple layers of alternating layers including different materials. For example, the superlattice layer 124 may have a structure in which a layer made of AlGaN and a layer made of AlN are repeatedly stacked. That is, AlGaN/AlN/AlGaN/AlN/AlGaN/AlN may be sequentially stacked to form the superlattice layer 124.

The high resistance layer 126 may be made of a material with low conductivity so that it may be electrically insulated between the substrate 110 and the main channel layer 132. The high resistance layer may include one or more material selected from Group III-V materials, such as nitrides including Al, Ga, In, B, or a combination thereof. The high resistance layer 126 may be AlₓIn_{y}Ga_{1-x-y}N (0≤x≤1, 0≤y≤1, x+y≤1). For example, the high resistance layer 126 may include AlN, GaN, InN, InGaN, AlGaN, AlInN, AlInGaN, or a combination thereof. The high resistance layer 126 may be made of a single layer or multiple layers.

Subsequently, a main channel layer 132 and a barrier layer 136 may be sequentially formed on the high resistance layer 126 in the main element area TA and peripheral circuit area PA.

In some embodiments, the main channel layer 132 and the barrier layer 136 may be formed sequentially using an epitaxial growth method. For example, the main channel layer 132 may be formed on the high resistance layer 126, and the barrier layer 136 may be formed on the main channel layer 132.

The main channel layer 132 and the barrier layer 136 may be made of the same-based semiconductor material. However, the material composition ratio of each layer may be different considering the role of each layer and the performance required for the semiconductor device. The main channel layer 132 and the barrier layer 136 may include one or more materials selected from Group III-V materials, such as nitrides including Al, Ga, In, B, or combinations thereof. The main channel layer 132 and the barrier layer 136 may be AlₓIn_{y}Ga_{(1-x-y)}N (0≤x≤1, 0≤y≤1, x+y≤1). For example, the main channel layer 132 and the barrier layer 136 may be AlN, GaN, InN, InGaN, AlGaN, AlInN, AlInGaN, or a combination thereof. For example, the barrier layer 136 may include a material having a different energy band gap than the main channel layer 132. The barrier layer 136 may have a higher energy band gap than the main channel layer 132.

As an example, the substrate 110 may include Si, the seed layer 121 may include AlN, and the superlattice layer 124 may include AlGaN and AlN. The high resistance layer 126 may include GaN, the main channel layer 132 may include GaN, and the barrier layer 136 may include AlGaN. The main channel layer 132 and the barrier layer 136 may be impurity doped or not.

As the lattice structure of Si and the lattice structure of GaN are different, it may not be easy to grow the main channel layer 132 made of GaN directly on the substrate 110 made of Si. In the method of manufacturing the semiconductor device according to some implementations, the seed layer 121, the superlattice layer 124, and the high resistance layer 126 are first formed on the substrate 110, and then the main channel layer 132 may be formed, so that the lattice structure of the main channel layer 132 may be stably formed.

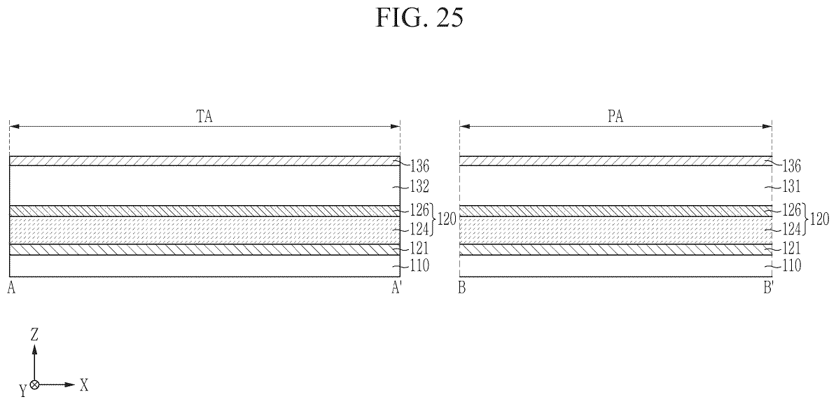

Referring to FIG. 25, the main channel layer 132 and the channel pattern 131 may be separated from each other by performing an ion implant process on at least part of the barrier layer 136. For example, a separation structure may be formed by performing an ion implant process on the portion of the barrier layer 136 positioned between the main element area TA and the peripheral circuit area PA. At this time, the separation structure may recess at least part of the main channel layer 132, but the disclosure is not limited thereto. As the separation structure is formed, the main channel layer 132 and channel pattern 131 may be separated from each other. However, it is not limited thereto, a trench penetrating the barrier layer 136 may be formed between the main element area TA and the peripheral circuit area PA to separate the main channel layer 132 and the channel pattern 131 from each other.

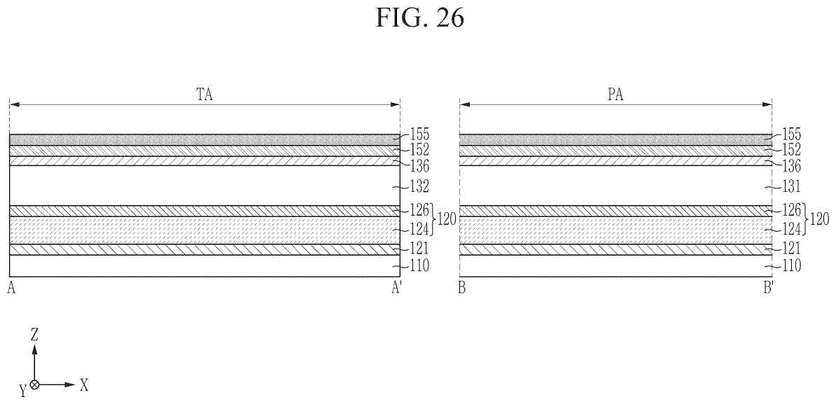

As shown in FIG. 26, a gate semiconductor material layer 152a and a gate electrode material layer 155a may be formed sequentially on the barrier layer 136 in the main element area TA and the peripheral circuit area PA.

First, the gate semiconductor material layer 152a may be formed on the barrier layer 136. The gate semiconductor material layer 152a may be formed using an epitaxial growth method.

The gate semiconductor material layer 152a may be made of the same-based semiconductor material as the main channel layer 132 and the barrier layer 136. However, the material composition ratio of each layer may be different considering the role of each layer and the performance required for the semiconductor device. The gate semiconductor material layer 152a may include a material having a different energy band gap than the barrier layer 136. For example, the gate semiconductor material layer 152a may include GaN and may be doped with impurity. The gate semiconductor material layer 152a may be doped with a P-type impurity, for example, magnesium (Mg).

Subsequently, the gate electrode material layer 155a may be formed on the gate semiconductor material layer 152a. The gate semiconductor material layer 152a is positioned between the barrier layer 136 and the gate electrode material layer 155a.

The gate electrode material layer 155a may be formed using a deposition process. For example, the gate electrode material layer 155a may be formed using at least one of a physical vapor deposition (PVD), a thermal chemical vapor deposition (a thermal CVD), a low pressure chemical vapor deposition (LP-CVD), a plasma enhanced chemical vapor deposition (PE-CVD), or an atomic layer deposition (ALD) technologies, but it is not limited thereto.

The gate electrode material layer 155a may include a conductive material. For example, the gate electrode material layer 155a may include a metal, a metal alloy, a conductive metal nitride, a metal silicide, a doped semiconductor material, a conductive metal oxide, or a conductive metal oxynitride, the like. For example, the gate electrode material layer 155a may include titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonizationnitride (TiAlC—N), titanium aluminum carbide (TiAlC), titanium carbide (TiC), tantalum carbonizationnitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or combination thereof, but it is not limited thereto. The gate electrode material layer 155a may be made of a single layer or multiple layers.

Next, as shown in FIG. 23, by patterning the gate electrode material layer 155a and the gate semiconductor material layer 152a by using a photo and etching process, a gate electrode 155 and a gate semiconductor layer 152 may be formed on the main element area TA.

For example, a hard mask layer and a photoresist layer may be formed sequentially on the gate electrode material layer 155a. A photoresist pattern may be formed by patterning the photoresist layer by using a photo process. A hard mask pattern may be formed by etching the hard mask layer using the photoresist pattern as a mask. At this time, at least part of the gate electrode material layer 155a may be removed during the process of etching the hard mask layer. Subsequently, by etching the gate semiconductor material layer 152a by using the hard mask pattern as a mask, at least a portion of the gate semiconductor material layer 152a may be removed. Accordingly, the remaining portion of the gate electrode material layer 155a may become the gate electrode 155. Additionally, the portion of the gate semiconductor material layer 152a that remains may become gate semiconductor layer 152. The gate semiconductor layer 152 is positioned between the barrier layer 136 and the gate electrode 155. The gate electrode 155 may be Schottky-contacted or ohmic-contacted to the gate semiconductor layer 152.

By patterning the gate semiconductor material layer 152a and the gate electrode material layer 155a by using the same mask, the gate semiconductor layer 152 and the gate electrode 155 may have the same pattern. That is, the gate semiconductor layer 152 and the gate electrode 155 may have the same planar shape. In the cross-section, the gate semiconductor layer 152 and the gate electrode 155 may have the same width. The gate semiconductor layer 152 may completely overlap with the gate electrode 155 in the vertical direction, and the upper surface of the gate semiconductor layer 152 may be entirely covered by the gate electrode 155, but it is not limited thereto. For example, the gate semiconductor layer 152 and the gate electrode 155 may partially overlap in the vertical direction. However, it is not limited thereto, for example, the gate electrode 155 and the gate semiconductor layer 152 may have different widths. At this time, the gate electrode 155 and the gate semiconductor layer 152 may be patterned using different masks. For example, the gate electrode 155 may be patterned using a photoresist pattern, and the gate semiconductor layer 152 may be patterned using a hard mask pattern.

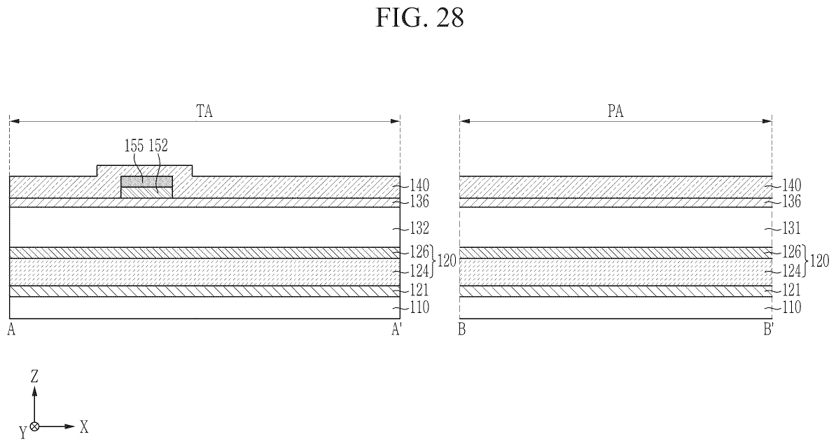

As shown in FIG. 28, a lower protection layer 150 may be formed on the barrier layer 136 and the gate electrode 155. For example, the protective layer 140 may be formed to cover the barrier layer 136 and the gate electrode 155 of the main element area TA, and the barrier layer 136 of the peripheral circuit area PA. The protective layer 140 may include an insulating material. For example, the protective layer 140 may include oxide such as SiO₂ or Al₂O₃. As another example, the protective layer 140 may include nitride such as SiN or oxynitride such as SiON.

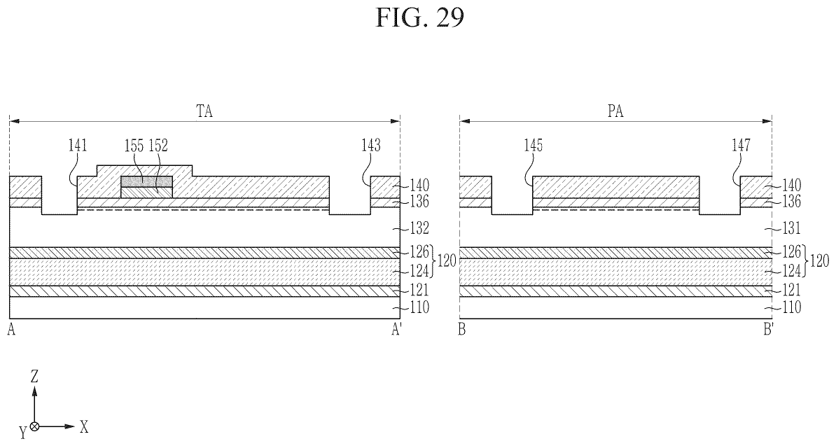

As shown in FIG. 29, by patterning the protective layer 140 by using a photo and etching processes, a first trench 141 and a second trench 143 may be formed in the main element area TA, and a third trench 145 and a fourth trench 147 may be formed in peripheral circuit area PA. there is. At this time, not only the protective layer 140 but also the barrier layer 136, the main channel layer 132, and the channel pattern 131 may be patterned together.

For example, a photoresist pattern may be formed on the protective layer 140, and the protective layer 140, the barrier layer 136, the main channel layer 132, and may channel pattern 131 may be sequentially etched using this as a mask. At this time, the protective layer 140 and the barrier layer 136 may be penetrated by the first trench 141 and the second trench 143, and the upper surface of the main channel layer 132 may be recessed. The main channel layer 132 may not be penetrated by the first trench 141 or the second trench 143. Additionally, the protective layer 140 and the barrier layer 136 may be penetrated by the third trench 145 and the fourth trench 147, and the upper surface of the channel pattern 131 may be recessed. The channel pattern 131 may not be penetrated by the third trench 145 or the fourth trench 147.

At this time, the depth at which the upper surface of the main channel layer 132 and the upper surface of the channel pattern 131 are recessed may be much smaller than the entire thickness of the main channel layer 132. Additionally, the depth at which the upper surface of the main channel layer 132 and the upper surface of the channel pattern 131 are recessed may be smaller than the thickness of the barrier layer 136. However, the disclosure is not limited to the above, and the depth at which the upper surface of the main channel layer 132 and the upper surface of the channel pattern 131 are recessed may be changed in various ways.

The sides of the protective layer 140 and the barrier layer 136 may be exposed to the outside by the first trench 141 and the second trench 143, and the upper and side surfaces of the main channel layer 132 may be exposed. The main channel layer 132 may form the bottom surface and sidewall of the first trench 141 and the second trench 143, and the barrier layer 136 may form the sidewall of the first trench 141 and the second trench 143. Additionally, the sides of the protective layer 140 and the barrier layer 136 may be exposed to the outside by the third trench 145 and the fourth trench 147, and the upper and side surfaces of the channel pattern 131 may be exposed. The channel pattern 131 may form the bottom surface and sidewall of the third trench 145 and the fourth trench 147, and barrier layer 136 may form the sidewall of the third trench 145 and the fourth trench 147.

The first trench 141 and the second trench 143 may be spaced apart from each other. The first trench 141 and the second trench 143 may be positioned on both sides of the gate electrode 155. The first trench 141 may be positioned on one side of the gate electrode 155 to be spaced apart from the gate electrode 155. The second trench 143 may be positioned on the other side of the gate electrode 155 to be spaced apart from the gate electrode 155. The distance that the first trench 141 is separated from the gate electrode 155 may be smaller than the distance that the second trench 143 is separated from the gate electrode 155. The shapes such as the width and the depth of the first trench 141 and the second trench 143 are shown to be similar, but are not limited thereto. The shapes of the first trench 141 and the second trench 143 may be changed in various ways. Additionally, the third trench 145 and the fourth trench 147 may be spaced apart from each other.

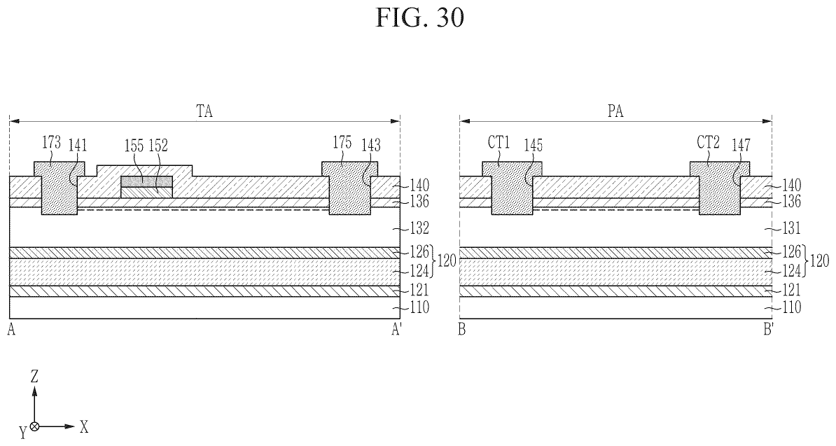

As shown in FIG. 30, a conductive material may be deposited in the first trench 141 to the fourth trench 147, and patterned to form a first contact electrode CT1 and a second contact electrode CT2 in the peripheral circuit area PA, and a source electrode 173 and a drain electrode in the main element area TA. 175.

In some embodiments, the first contact electrode CT1 may be formed to fill the interior of the third trench 145. Within the third trench 145, the first contact electrode CT1 may be in contact with the channel pattern 131 and the barrier layer 136. The first contact electrode CT1 may be in contact with the sides of the channel pattern 131 and the barrier layer 136. The first contact electrode CT1 may cover the sides of the channel pattern 131 and the barrier layer 136. The first contact electrode CT1 may be electrically connected to the channel pattern 131 through the third trench 145. The upper surface of the first contact electrode CT1 may be protruded from the upper surface of the protective layer 140.

The second contact electrode CT2 may be formed to fill the interior of the fourth trench 147. Within the fourth trench 147, the second contact electrode CT2 may be in contact with the channel pattern 131 and the barrier layer 136. The second contact electrode CT2 may be in contact with the side surfaces of the channel pattern 131 and the barrier layer 136. The second contact electrode CT2 may cover the sides of the channel pattern 131 and the barrier layer 136. The second contact electrode CT2 may be electrically connected to the channel pattern 131 through the fourth trench 147. The upper surface of the second contact electrode CT2 may be protruded from the upper surface of the protective layer 140.

In some embodiments, the first contact electrode CT1 and the second contact electrode CT2 may be in ohmic contact with channel pattern 131. At this time, the first contact interface CF1 between the first contact electrode CT1 and the second drift area DTR2 and the second contact interface CF2 between the second contact electrode CT2 and the second drift area DTR2 may have a resistance component. Specifically, in the process where the carrier passing through the 2-dimensional electron gas 134 passes through at least part of the channel pattern 131, that is, the upper part of the 2-dimensional electron gas 134, and is transferred to the first contact electrode CT1 and the second contact electrode CT2, the first contact interface CF1 between first contact electrode CT1 and second drift area DTR2, and the second contact interface CF2 between the second contact electrode CT2 and the second drift area DTR2 may have a predetermined resistance value. That is, the first contact interface CF1 and the second contact interface CF2 may function as resistances with predetermined resistance values. At this time, a first contact resistance of the first contact interface CF1 (RC1 in FIG. 7) and a second contact resistance of the second contact interface CF2 (RC2 in FIG. 7) may have different values depending on the temperature. For example, the first contact resistance of the first contact interface CF1 (RC1 in FIG. 7) and the second contact resistance of the second contact interface CF2 (RC2 in FIG. 7) may decrease as the temperature increases. That is, the first contact resistance of the first contact interface CF1 (RC1 in FIG. 7) and the second contact resistance of the second contact interface CF2 (RC2 in FIG. 7) may have a temperature resistance coefficient of a negative sign.

Additionally, the second drift area DTR2 may have a resistance component. In other words, the second drift area DTR2 may function as a resistor with a predetermined resistance value. At this time, the resistance RD of the second drift area DTR2 (RD in FIG. 7) may have different values depending on temperature. For example, the resistance RD of the second drift area DTR2 (RD in FIG. 7) may increase as a temperature increases. In other words, the resistance RD of the second drift area DTR2 (RD in FIG. 7) may have a positive sign temperature coefficient of resistance.

In some embodiments, the source electrode 173 may be formed to fill the interior of the first trench 141. Within the first trench 141, the source electrode 173 may be in contact with the main channel layer 132 and the barrier layer 136. The source electrode 173 may be in contact with the sides of the main channel layer 132 and the barrier layer 136. The source electrode 173 may cover the sides of the main channel layer 132 and the barrier layer 136. The source electrode 173 may be electrically connected to the main channel layer 132 through the first trench 141. The upper surface of the source electrode 173 may be protruded from the upper surface of the protective layer 140.

The drain electrode 175 may be formed to fill the interior of the second trench 143. Within the second trench 143, the drain electrode 175 may be in contact with the main channel layer 132 and the barrier layer 136. The drain electrode 175 may be in contact with the sides of the main channel layer 132 and the barrier layer 136. The drain electrode 175 may cover the sides of the main channel layer 132 and the barrier layer 136. The drain electrode 175 maybe electrically connected to the main channel layer 132 through the second trench 143. The upper surface of the drain electrode 175 may be protruded from the upper surface of the protective layer 140.

The source electrode 173 and the drain electrode 175 may be in ohmic contact with the main channel layer 132. The area in contact with the source electrode 173 and the drain electrode 175 within the main channel layer 132 may be doped with a relatively high concentration compared to other areas. For example, the main channel layer 132 may be doped by an ion implant process, annealing process, etc. However, the disclosure is not limited to the above, and the doping process of the main channel layer 132 may be comprised of various other processes. The doping process of the main channel layer 132 may be performed before forming the source electrode 173 and drain electrode 175. In some cases, the main channel layer 132 may not be doped.

Inside the main channel layer 132, a 2-dimensional electron gas 134 may be formed in a portion adjacent to the barrier layer 136. The 2-dimensional electron gas 134 may be positioned at the interface between the main channel layer 132 and the barrier layer 136. The 2-dimensional electron gas 134 may be positioned in the first drift area DTR1 between the source electrode 173 and the drain electrode 175. A depletion area DPR may be formed within the main channel layer 132 by the gate semiconductor layer 152 having a different energy band gap from the barrier layer 136. Accordingly, the semiconductor device according to some implementations may have a normally off characteristic. That is, the semiconductor device according to some implementations may be a normally off high electron mobility transistor (HEMT). In the gate off state, the 2-dimensional electron gas 134 may be positioned within the first drift area DTR1 excluding the depletion area DPR of the main channel layer 132. In the gate-on state, the flow of the 2-dimensional electron gas 134 continues within the depletion area DPR, thereby the 2-dimensional electron gas 134 may be positioned overall within the first drift area DTR1.

In the step of forming the source electrode 173 and the drain electrode 175, a field dispersed layer may be formed together. The field dispersed layer may be positioned between the source electrode 173 and the drain electrode 175. The field dispersed layer may overlap the gate electrode 155. The field dispersed layer may be electrically connected to the source electrode 173. The field dispersed layer may be formed integrally with the source electrode 173. The field dispersed layer may include the same material as the source electrode 173 and may be positioned in the same layer as the source electrode 173.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While this disclosure has been described in connection with what is presently considered to be practical examples, it is to be understood that the disclosure is not limited to the disclosed embodiments, but, on the contrary, is intended to cover various modifications and equivalent arrangements included within the spirit and scope of the appended claims.

What is claimed is:

1. A semiconductor device comprising:
a substrate;
a channel pattern that extends in a direction over the substrate, wherein the channel pattern includes a drift area with a 2-dimensional electron gas, and wherein the channel pattern includes gallium nitride; and
a first contact electrode and a second contact electrode that are in contact with a side of the drift area, wherein the first contact electrode and the second contact electrode are spaced apart from each other in the direction,
wherein a resistance of the drift area has a positive temperature coefficient of resistance,
wherein a first contact resistance between the first contact electrode and the channel pattern and a second contact resistance between the second contact electrode and the channel pattern have a negative temperature coefficient of resistance, and
wherein a sum of (i) the resistance of the drift area of the channel pattern positioned between the first contact electrode and the second contact electrode, (ii) the first contact resistance, and (iii) the second contact resistance is constant regardless of a temperature.

2. The semiconductor device of claim 1, wherein:
a length of the channel pattern between the first contact electrode and the second contact electrode along the direction is 1 μm to 10 μm.

3. The semiconductor device of claim 2, wherein:
the length of the channel pattern between the first contact electrode and the second contact electrode along the direction is 3 μm to 4 μm.

4. The semiconductor device of claim 2, wherein:
the first contact electrode and the second contact electrode include titanium, titanium nitride, aluminum, or any combination thereof.

5. The semiconductor device of claim 1, further comprising:
a barrier layer positioned on the channel pattern and including aluminum gallium nitride, and
the first contact electrode and the second contact electrode extend through the barrier layer.

6. The semiconductor device of claim 1, wherein:
a width of the channel pattern along a second direction that intersects the direction is the same as a length of a boundary defined by the channel pattern and the first contact electrode along the second direction.

7. A semiconductor device including a main element area and a peripheral circuit area positioned on at least one side of the main element area,
wherein the main element area includes
a main channel layer,
a barrier layer positioned above the main channel layer and including a material having a different energy band gap from the main channel layer,
a gate electrode positioned above the barrier layer,
a gate semiconductor layer positioned between the barrier layer and the gate electrode,
a source electrode and a drain electrode positioned on both sides of the gate electrode and connected to the main channel layer, and
a protective layer covering the barrier layer and the gate electrode,
wherein the peripheral circuit area includes
a channel pattern including a drift area with a 2-dimensional electron gas, wherein the channel pattern includes the same material as the main channel layer,
a resistance unit positioned on the channel pattern, wherein the resistance unit includes the same material as the source electrode, and wherein the resistance unit has a first contact electrode and a second contact electrode spaced apart from each other in a direction, and
a length of the channel pattern between the first contact electrode and the second contact electrode is 1 μm to 10 μm along the direction.

8. The semiconductor device of claim 7, wherein:
a resistance of the drift area has a positive temperature coefficient of resistance, and
a first contact resistance between the first contact electrode and the channel pattern and a second contact resistance between the second contact electrode and the channel pattern have a negative temperature coefficient of resistance.

9. The semiconductor device of claim 8, wherein:
a resistance of the resistance unit is defined as a sum of (i) the resistance of the drift area of the channel pattern positioned between the first contact electrode and the second contact electrode, (ii) a first contact resistance between the first contact electrode and the channel pattern, and (iii) a second contact resistance between the second contact electrode and the channel pattern, and
the resistance of the resistance unit at the first temperature is the same as the resistance of the resistance unit at a second temperature that is different from the first temperature.

10. The semiconductor device of claim 7, further comprising:
a barrier layer positioned above the channel pattern in the peripheral circuit area and including AlGaN, and
the first contact electrode and the second contact electrode extend through the barrier layer.

11. The semiconductor device of claim 7, wherein:
the channel pattern is integrated with the main channel layer.

12. The semiconductor device of claim 11, further comprising:
a separation structure positioned above the channel pattern between the peripheral circuit area and the main element area, wherein the separation structure extends through the barrier layer.

13. The semiconductor device of claim 7, wherein:
the length of the channel pattern between the first contact electrode and the second contact electrode along the direction is 3 μm to 4 μm.

14. The semiconductor device of claim 7, wherein:
the resistance unit includes a first resistance unit and a second resistance unit, and
a length of a first channel pattern of the first resistance unit along the direction is the same as a length of a second channel pattern of the second resistance unit along the direction.

15. The semiconductor device of claim 7, wherein:
at least one of the first contact electrode or the second contact electrode of the resistance unit is electrically connected to at least one of the source electrode, the drain electrode, or the gate electrode of the main element area.

16. A semiconductor device including a main element area and a peripheral circuit area, wherein the peripheral circuit is positioned on a side of the main element area and includes a plurality of resistance units,
wherein the main element area includes
a main channel layer including gallium nitride,
a barrier layer positioned on the main channel layer and including aluminum gallium nitride,
a gate electrode positioned on the barrier layer,
a gate semiconductor layer positioned between the barrier layer and the gate electrode and including gallium nitride doped with a P-type impurity,
a source electrode and a drain electrode positioned on both sides of the gate electrode and connected to the main channel layer, and
a protective layer covering the barrier layer and the gate electrode,
wherein each resistance unit of the plurality of resistance units includes
a channel pattern extending in a direction and integrated with the main channel layer, and
a first contact electrode and a second contact electrode positioned on the channel pattern, wherein the first contact electrode and the second contact electrode include the same material as the source electrode, and wherein the first contact electrode and the second contact electrode are spaced apart from each other in the direction, and
wherein a length of the channel pattern along the direction between the first contact electrode and the second contact electrode in one resistance unit of the plurality of resistance units is the same as a length of the channel pattern along the direction between the first contact electrode and the second contact electrode in other resistance units of the plurality of resistance units.

17. The semiconductor device of claim 16, wherein:
the length of the channel pattern along the direction between the first contact electrode and the second contact electrode of each resistance unit of the plurality of resistance units is 1 μm to 10 μm.

18. The semiconductor device of claim 16, wherein:
the barrier layer is further positioned on the channel pattern.

19. The semiconductor device of claim 16, wherein:
at least one resistance unit of the plurality of resistance units is electrically connected to at least one of the source electrode, the drain electrode, or the gate electrode in the main element area.

20. The semiconductor device of claim 16, further comprising:
a separation structure positioned between the plurality of resistance units in the peripheral circuit area,
wherein the separation structure extends through the barrier layer.
